(19) United States
(12) Patent Application Publication
(10) Pub. No.: US 2026/0101552 A1
(43) Pub. Date: Apr. 9, 2026

(54) BACKSIDE REPLACEMENT METAL GATE FOR STACKED TRANSISTORS

(71) Applicant: International Business Machines Corporation, Armonk, NY (US)

(72) Inventors: Shravana Kumar Katakam, Lehi, UT (US); Ruilong Xie, Niskayuna, NY (US); Takashi Ando, Eastchester, NY (US); Viswas Purohit, East Amherst, NY (US); Kishwar Mashooq, Albany, NY (US); Shay Reboh, Guilderland, NY (US); Paul Charles Jamison, Averill Park, NY (US)

(21) Appl. No.: 18/910,274

(22) Filed: Oct. 9, 2024

(51) Int. Cl. H01L 29/08; H01L 21/822; H01L 21/8238; H01L 27/06; H01L 27/092; H01L 29/06; H01L 29/423; H01L 29/66; H01L 29/775; H01L 29/786

(52) U.S. Cl. CPC H10D 62/151; H10D 30/014; H10D 30/43; H10D 30/6735; H10D 30/6757; H10D 62/121; H10D 84/017; H10D 84/038; H10D 84/856; H10D 88/00; H10D 88/01

(57) ABSTRACT

Embodiments include a semiconductor structure including an upper transistor having a first work function material disposed over a lower transistor. The lower transistor includes a gate dielectric material and a second work function material such that a bottom portion of the gate dielectric material has an opening. An extension of the second work function material extends through the opening.

### BACKGROUND

The present invention generally relates to fabrication methods and resulting structures for integrated circuits (ICs), and more specifically, to fabrication methods and resulting structures configured and arranged to employ backside replacement metal gate (RMG) for shifted stacked transistors.

ICs (also referred to as a chip or a microchip) include electronic circuits on a wafer. The wafer is a semiconductor material, such as, for example, silicon or other materials. An IC is formed of a large number of devices, such as transistors, capacitors, resistors, etc., which are formed in layers of the IC and interconnected with wiring in the back-end-of-line (BEOL) layers of the wafer. on the wafer. Typical ICs are formed by first fabricating individual semiconductor devices using processes referred to generally as the front-end-of-line (FEOL). A metal-oxide-semiconductor field-effect transistor (MOSFET) is a transistor used for amplifying or switching electronic signals. The MOSFET has a source, a drain, and a metal oxide gate electrode. A conventional FET is a planar device where the entire channel region of the device is formed parallel and slightly below the planar upper surface of the semiconducting substrate. In contrast to a planar FET, there are so-called three-dimensional (3D) devices, such as a FinFET device, which is a three-dimensional structure. One type of device for advanced integrated circuit products is generally known as a nanosheet transistor. In general, a nanosheet transistor has a fin-type channel structure that includes a plurality of vertically spaced-apart sheets of semiconductor material. A gate structure for the device is positioned around each of these spaced-apart layers of channel semiconductor material.

### SUMMARY

Embodiments of the present invention are directed to implementing backside replacement metal gate (RMG) for shifted stacked transistors. A semiconductor structure includes an upper transistor having a first work function material disposed over a lower transistor, the lower transistor including a gate dielectric material and a second work function material such that a bottom portion of the gate dielectric material includes an opening. An extension of the second work function material extends through the opening.

According to one or more embodiments, a method includes providing an upper transistor having a first work function material disposed over a lower transistor, the lower transistor having a gate dielectric material with an opening in a bottom portion. The model includes forming the lower transistor with a second work function material such that an extension of the second work function material extends through the opening.

According to one or more embodiments, a method of forming a semiconductor structure includes forming an upper transistor above a lower transistor, the upper transistor having a first work function material filled from a first side of the semiconductor structure. The method includes filling the lower transistor with a second work function material from a second side opposite the first side of the semiconductor structure.

Other embodiments of the present invention implement features of the above-described devices/structures in methods and/or implement features of the methods in devices/structures.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIGS. 1A, 1B, 1C, 1D, and 1E respectively depict a top view and cross-sectional views of a portion of an integrated circuit (IC) under-fabrication after fabrication operations according to one or more embodiments;

FIGS. 2A, 2B, 2C, 2D, and 2E depict a top view and cross-sectional views of a portion of an IC under-fabrication after fabrication operations according to one or more embodiments;

FIGS. 3A, 3B, 3C, 3D, and 3E depict a top view and cross-sectional views of a portion of an IC under-fabrication after fabrication operations according to one or more embodiments;

FIGS. 4A, 4B, 4C, 4D, and 4E depict a top view and cross-sectional views of a portion of an IC under-fabrication after fabrication operations according to one or more embodiments;

FIGS. 5A, 5B, 5C, 5D, and 5E depict a top view and cross-sectional views of a portion of an IC under-fabrication after fabrication operations according to one or more embodiments;

FIGS. 6A, 6B, 6C, 6D, and 6E depict a top view and cross-sectional views of a portion of an IC under-fabrication after fabrication operations according to one or more embodiments;

FIGS. 7A, 7B, 7C, 7D, and 7E depict a top view and cross-sectional views of a portion of an IC under-fabrication after fabrication operations according to one or more embodiments;

FIGS. 8A, 8B, 8C, 8D, and 8E depict a top view and cross-sectional views of a portion of an IC under-fabrication after fabrication operations according to one or more embodiments;

FIGS. 9A, 9B, 9C, 9D, and 9E depict a top view and cross-sectional views of a portion of an IC under-fabrication after fabrication operations according to one or more embodiments;

FIGS. 10A, 10B, 10C, 10D, and 10E depict a top view and cross-sectional views of a portion of an IC under-fabrication after fabrication operations according to one or more embodiments;

FIGS. 11A, 11B, 11C, 11D, and 11E depict a top view and cross-sectional views of a portion of an IC under-fabrication after fabrication operations according to one or more embodiments;

FIGS. 12A, 12B, 12C, 12D, and 12E depict a top view and cross-sectional views of a portion of an IC under-fabrication after fabrication operations according to one or more embodiments;

FIGS. 13A, 13B, 13C, 13D, and 13E depict a top view and cross-sectional views of a portion of an IC under-fabrication after fabrication operations according to one or more embodiments;

FIGS. 14A, 14B, 14C, 14D, and 14E depict a top view and cross-sectional views of a portion of an IC under-fabrication after fabrication operations according to one or more embodiments;

FIGS. 15A, 15B, 15C, 15D, and 15E depict a top view and cross-sectional views of a portion of an IC under-fabrication after fabrication operations according to one or more embodiments;

FIGS. 16A, 16B, 16C, 16D, and 16E depict a top view and cross-sectional views of a portion of an IC under-fabrication after fabrication operations according to one or more embodiments;

FIGS. 17A, 17B, 17C, 17D, and 17E depict a top view and cross-sectional views of a portion of an IC under-fabrication after fabrication operations according to one or more embodiments;

FIGS. 18A, 18B, 18C, 18D, and 18E depict a top view and cross-sectional views of a portion of an IC under-fabrication after fabrication operations according to one or more embodiments;

FIGS. 19A, 19B, 19C, 19D, and 19E depict a top view and cross-sectional views of a portion of an IC under-fabrication after fabrication operations according to one or more embodiments;

FIG. 20 depicts a flowchart of a method of forming a semiconductor structure according to one or more embodiments; and

FIG. 21 depicts a flowchart of a method of forming a semiconductor structure according to one or more embodiments.

### DETAILED DESCRIPTION

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

The MOSFET is a transistor used for amplifying or switching electronic signals. The MOSFET has a source, a drain, and a metal gate electrode. The metal gate is electrically insulated from the main semiconductor n-channel or p-channel by a thin layer of insulating material, for example, silicon dioxide or glass, which makes the input resistance of the MOSFET relatively high. The gate voltage controls whether the current path from the source to the drain is an open circuit (“off”) or a resistive path (“on”). N-type field effect transistors (NFET) and p-type field effect transistors (PFET) are two types of complementary MOSFETs. The NFET includes n-doped source and drain junctions and uses electrons as the current carriers. The PFET includes p-doped source and drain junctions and uses holes as the current carriers.

The nanowire or nanosheet MOSFET is a type of MOSFET that uses multiple stacked nanowires/nanosheets to form multiple channel regions. The gate regions of a nanosheet MOSFET are formed by wrapping gate stack materials around the multiple nanowire/nanosheet channels. This configuration is known as a gate-all-around (GAA) FET structure. The nanowire/nanosheet MOSFET device mitigates the effects of short channels and reduces drain-induced barrier lowering.

The GAA nanosheet FET structures can provide superior electrostatics. In contrast to known Fin-type FET (FinFET) structures in which the fin element of the transistor extends “up” out of the transistor, nanosheet FET designs implement the fin as a silicon nanosheet/nanowire. In a known configuration of a GAA nanosheet FET, a relatively small FET footprint is provided by forming the channel region as a series of nanosheets (i.e., silicon nanowires). A GAA configuration includes a source region, a drain region, and stacked nanosheet channels between the source and drain regions. A gate surrounds the stacked nanosheet channels and regulates electron flow through the nanosheet channels between the source and drain regions. GAA nanosheet FETs are fabricated by forming alternating layers of channel nanosheets and sacrificial nanosheets. The sacrificial nanosheets are released from the channel nanosheets before the FET device is finalized.

Another nonplanar transistor architecture is the so-called stacked field effect transistor (FET). To increase the available computing power per unit area, a stacked FET (or SFETs) a vertical stack of two (or more) FETs over a shared substrate footprint. As one fabrication technique, two wafers are processed separately (i.e., semiconductor stacks are built on each wafer) and later joined via a wafer bonding process. The resultant stacked transistor architecture offers several improvements over planar and fin-type devices, such as the ability to build complementary devices (e.g., CMOS) at a reduced footprint. Although fabrication of stacked FETs may be challenging, efforts are ongoing to design stacked FET fabrication schemes and structures that are suitable for scaled production.

One or more embodiments improve fabrication methods and resulting structures for stacked FETs by using backside replacement metal gate (RMG) for the lower transistors in shifted stacked transistors. Filling the work function material of the lower transistor from the backside allows a different work function material to be utilized in the upper and lower transistors, such that the work function material of the lower transistor is not affected by previous fabrication step. This can result in transistors with different threshold voltage.

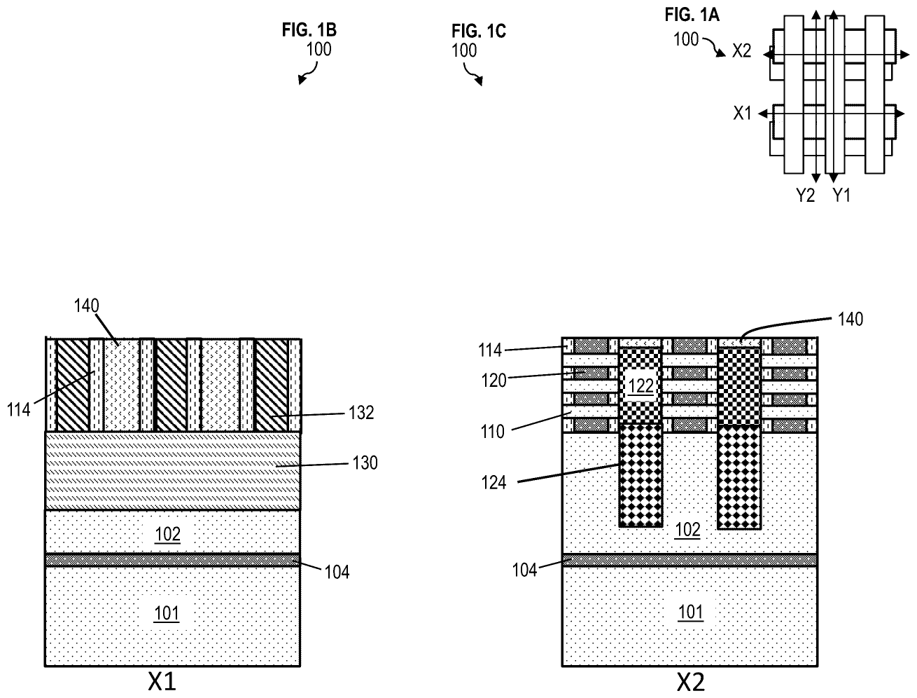

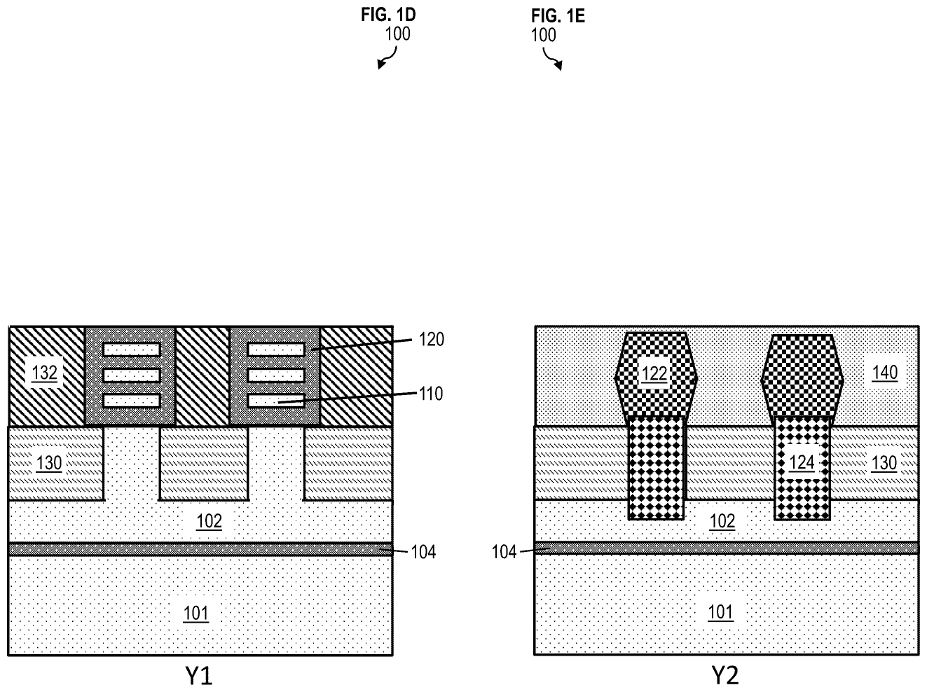

Turning now to a more detailed description of aspects of the present invention, FIG. 1A depicts a top view of a simplified illustration of a portion of an integrated circuit (IC) 100, FIG. 1B depicts a cross-sectional view taken along X1 of the IC 100, FIG. 1C depicts a cross-sectional view taken along X2 of the IC 100, FIG. 1D depicts a cross-sectional view taken along Y1 of the IC 100, and FIG. 1E depicts a cross-sectional view taken along Y2 of the IC 100. For ease of understanding, some layers may be omitted from the top view so as not to obscure the figure and to view layers underneath. The top view is intended to provide a simplified illustration and a general orientation, but the top view is not intended to be a complete representation of the device. Future locations of layers may be depicted in the top view to assist the reader. Standard semiconductor fabrication techniques can be utilized to fabricate the IC 100 as understood by one of ordinary skill in the art. Any suitable lithography processes including deposition techniques and etching techniques can be utilized herein.

FIGS. 1A, 1B, 1C, 1D, and 1E depict the IC 100 having a wafer where several known fabrication processes have been performed. A substrate 102 is over a lower substrate 101 with an (intervening) etch stop layer 104 in between. The substrate 102, lower substrate 101, and semiconductor layers 110 may be formed of silicon or other semiconductor materials. The etch stop layer 104 may be formed of silicon germanium.

Shallow trench isolation (STI) regions 130 are formed in the substrate 102. Material of the STI regions 130 can include low-k dielectric materials, ultra-low-k dielectric materials, etc. Backside contact placeholders 124 are formed in the substrate 102 as sacrificial material. Example materials of the backside contact placeholders 124 may include silicon germanium for etch selectivity in subsequent fabrication processes.

Self-aligned gate isolation material 132 is disposed on the substrate 102 and may include nitride materials such as silicon nitride (SiN). The materials of the self-aligned gate isolation material 132 are intended to be different from the interlayer dielectric layer and the inner spacers for etch selectivity.

Semiconductor layers 110 are above the substrate 102, and a dummy gate 120 is formed around the semiconductor layers 110. The dummy gate 120 can include silicon germanium or any other suitable material that provides etch selectivity. The semiconductor layers 110 are the channel regions for the lower transistors. The semiconductor layers 110 are nanosheets separated by inner spacers 114, and the nanosheets can have a thickness of, for example, 5 nanometers. The thickness of a nanosheet can range from about 2-10 nm, and other ranges are possible. Example materials of the inner spacers 114 can include SiN, SiBCN, SiOCN, SiOC, etc.

Source and drain (source/drain) regions 122 are connected to the semiconductor layers 110. The source/drain regions 122 include epitaxial material that can be doped with n-type or p-type dopants according to whether an n-type or p-type transistor is formed.

Interlayer/intralayer dielectric (ILD) material 140 is formed. The ILD material 140 can include low-k-dielectric materials, ultra-low-k dielectric materials, etc.

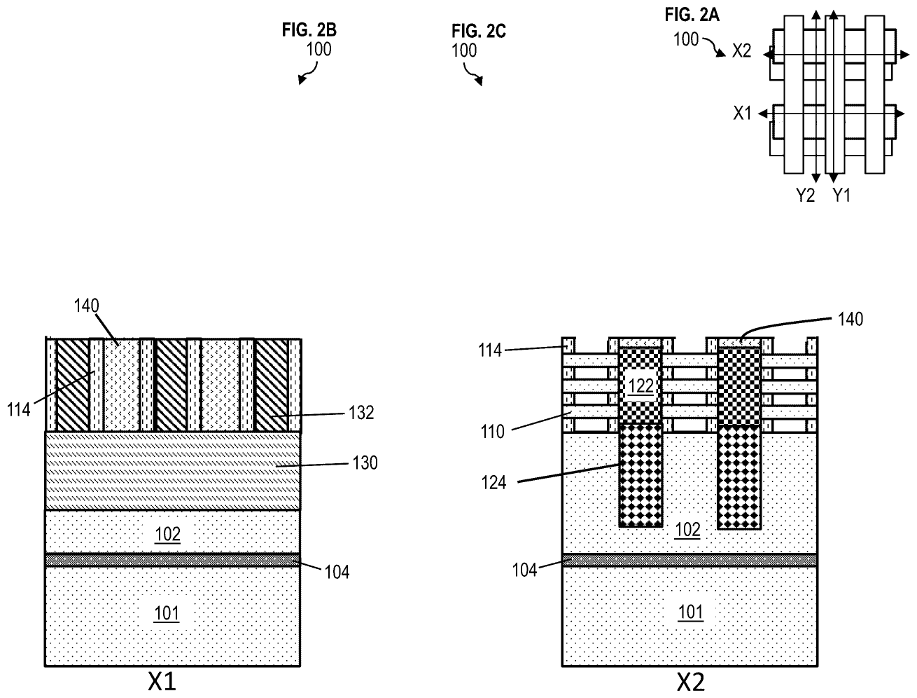

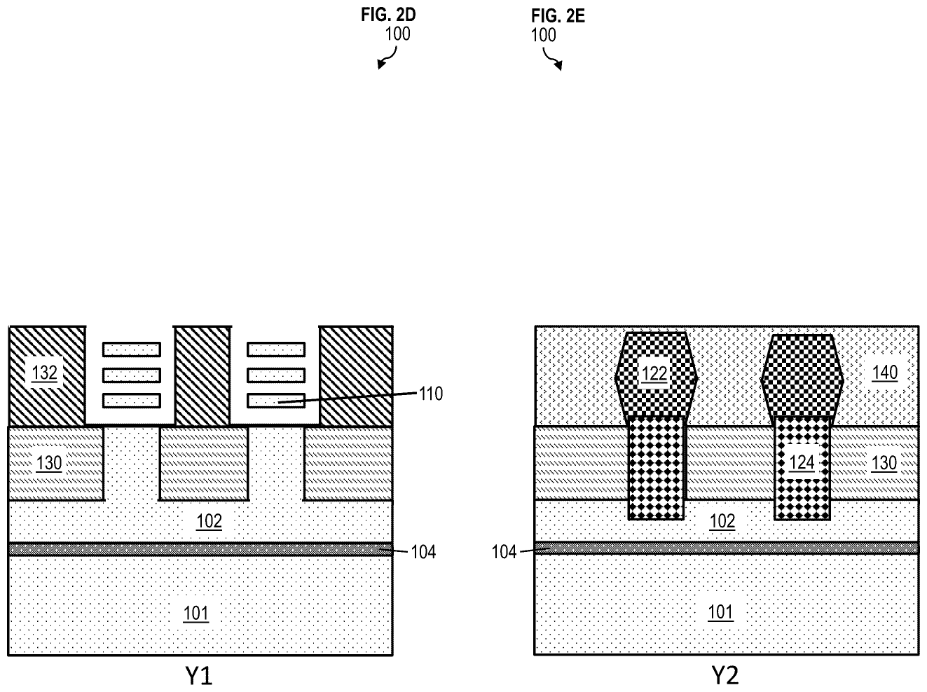

FIGS. 2A, 2B, 2C, 2D, and 2E depict the IC 100 after removing the sacrificial material of the dummy gate. The dummy gate 120 is removed such that openings are around the semiconductor layers 110.

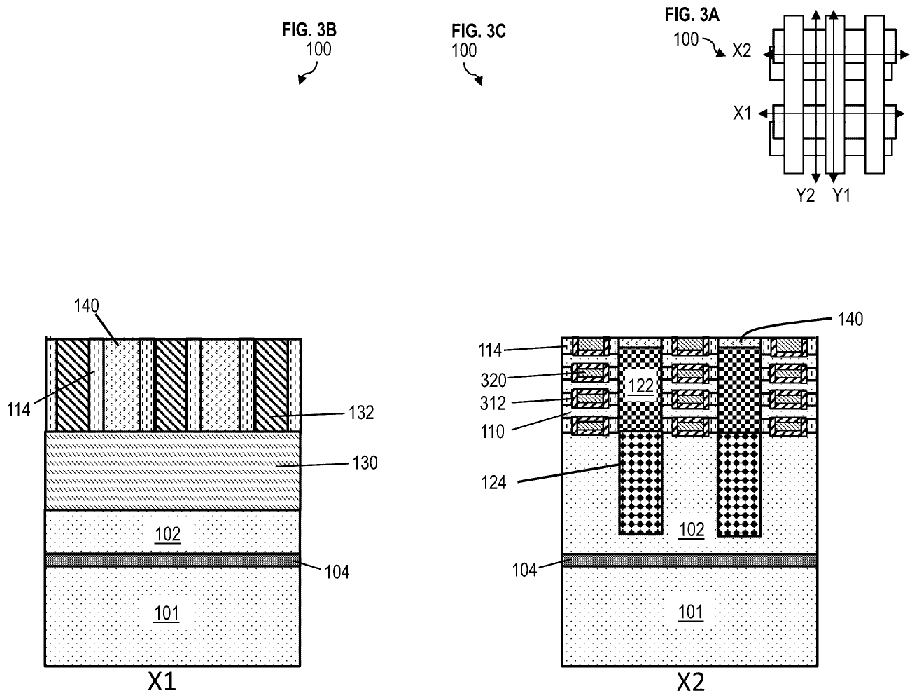

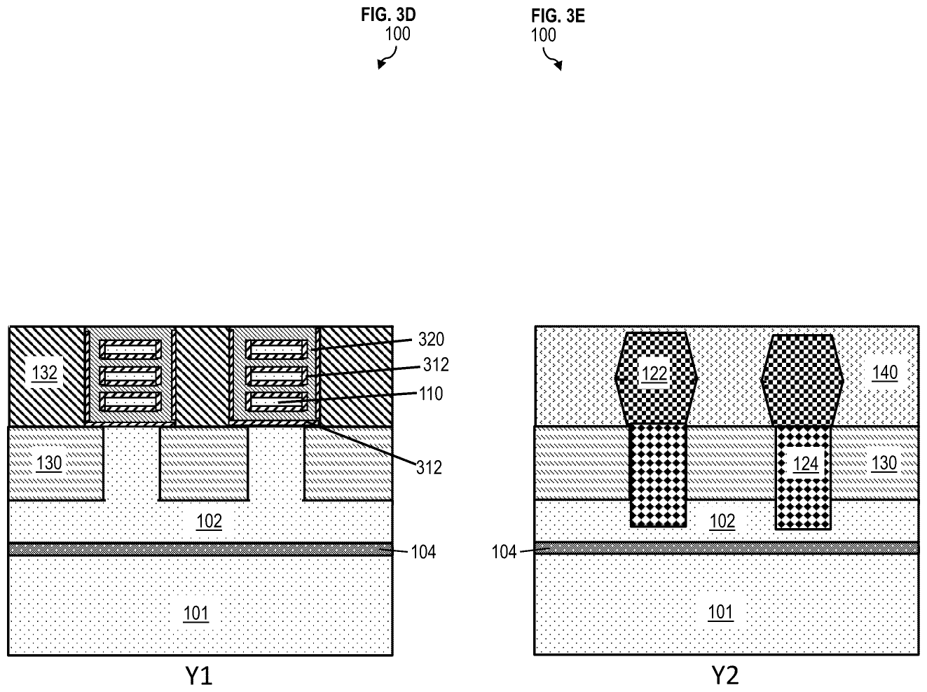

FIGS. 3A, 3B, 3C, 3D, and 3E depict the IC 100 after high-k dielectric material formation and fill material formation. High-k dielectric material 312 is formed around the semiconductor layers 110 in the openings. Various materials can be utilized for the high-k dielectric material 312. In one or more embodiments, examples of the high-k dielectric material 312 can include lanthanum oxide (LaOₓ) and aluminum oxide (AlOₓ). A fill material 320 is formed on the high-k dielectric material 312. The fill material 320 may be a stack of materials. The fill material 320 can include titanium nitride (TiN) with amorphous silicon (a-Si) formed/stacked on top of the TiN material. The amorphous silicon may be formed as a cap. Chemical mechanical polishing/planarization (CMP) can be performed to polish away an excess material.

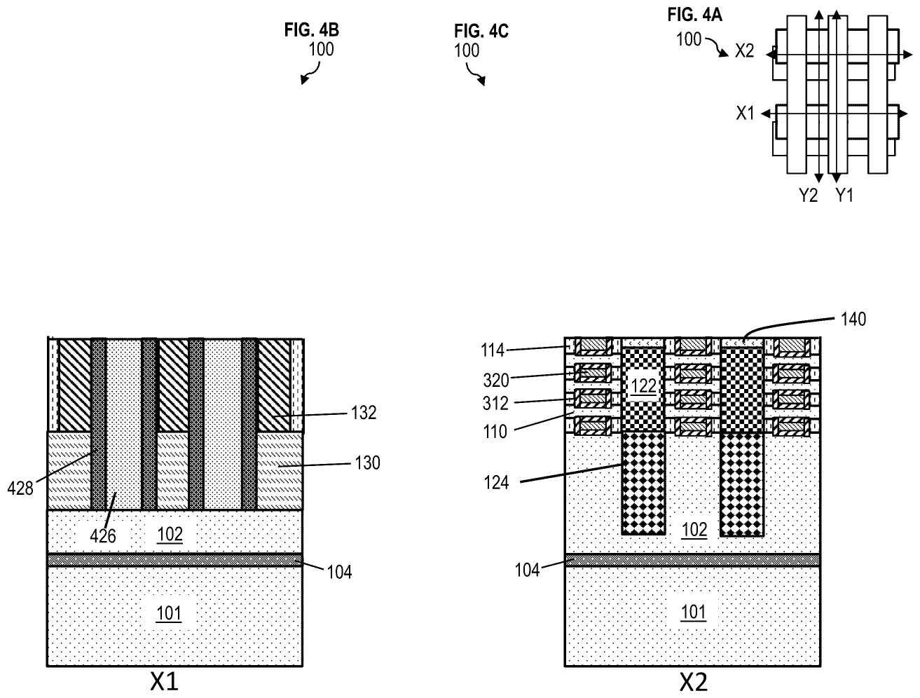

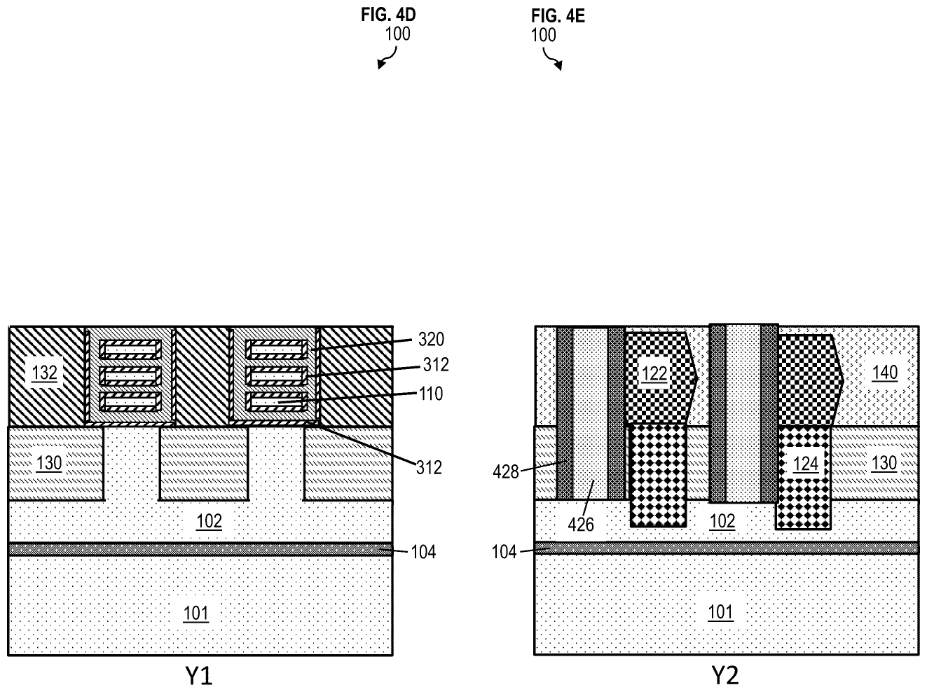

FIGS. 4A, 4B, 4C, 4D, and 4E depict the IC 100 after forming backside contact placeholders for the upper transistor. Backside contact placeholders 426 are formed through the ILD material 140, a portion of the source/drain regions 122, and the STI region 130. Dielectric spacers 428 can be disposed on the sides of the backside contact placeholders 426. The backside contact placeholders 426 can be formed of silicon germanium or any suitable material for etch selectivity during subsequent processing. The dielectric spacers 428 can include SiN, SiBCN, SiOCN, SiOC, etc.

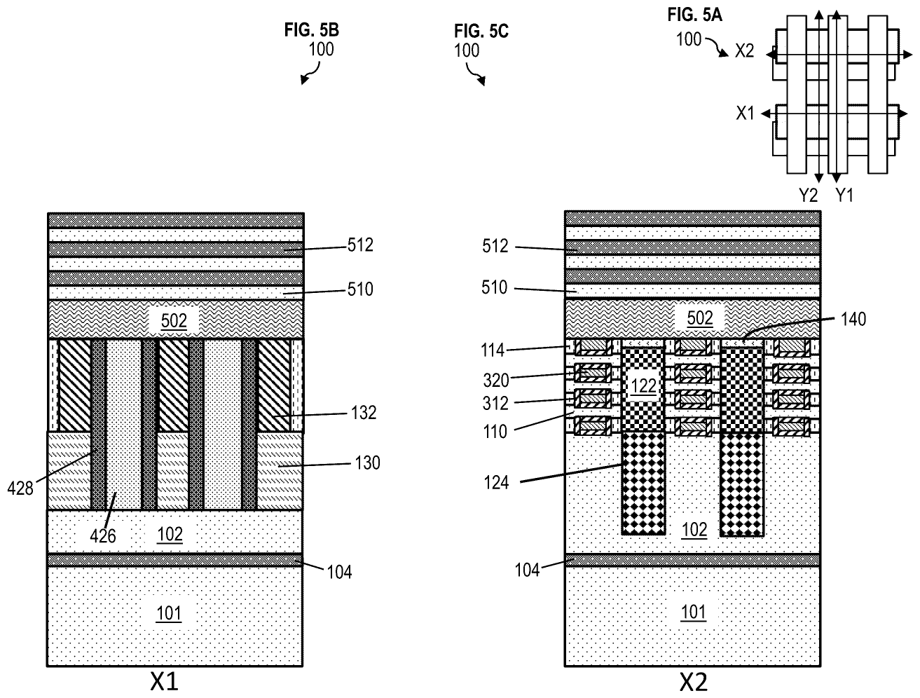

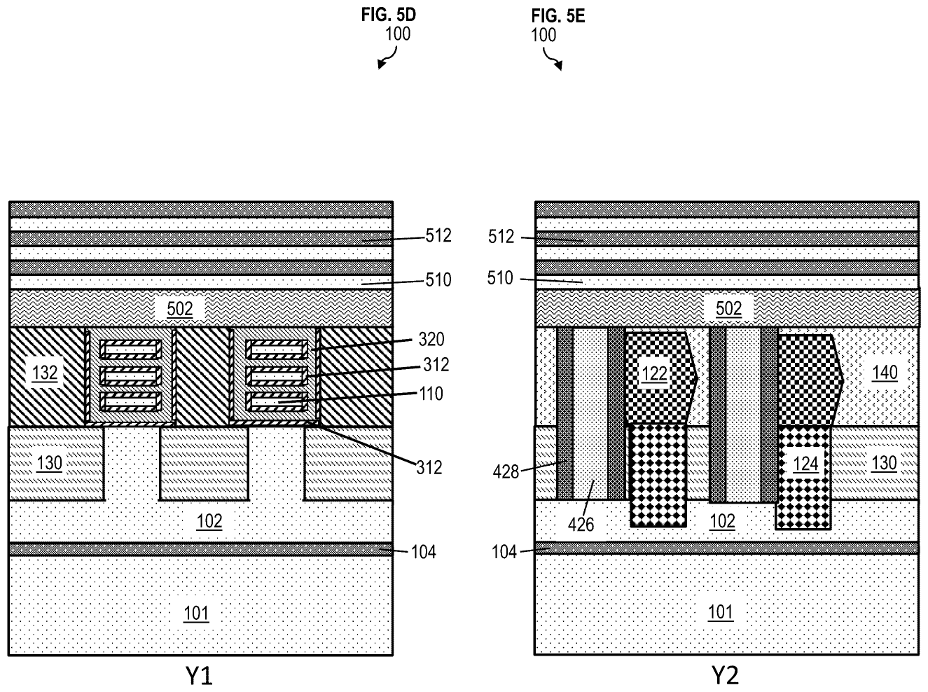

FIGS. 5A, 5B, 5C, 5D, and 5E depict the IC 100 after bonding a wafer with a nanosheet stack to the structure, and then grinding/polishing off the top wafer. A bonding layer 502 can be formed with a nanosheet stack on top. The bonding layer may include an oxide material, such as silicon dioxide (SiO₂) or other oxide materials. The nanosheet stack is formed with alternating layers of semiconductor layers 510 and sacrificial layers 512. The semiconductor layers 510 may include substantially pure silicon or other semiconductor material and are the channel regions for the upper transistors. The semiconductor layers 510 are nanosheets and can have a thickness ranging from about 2-10 nm, and other ranges are possible. The sacrificial layers 512 are formed of silicon germanium (SiGe).

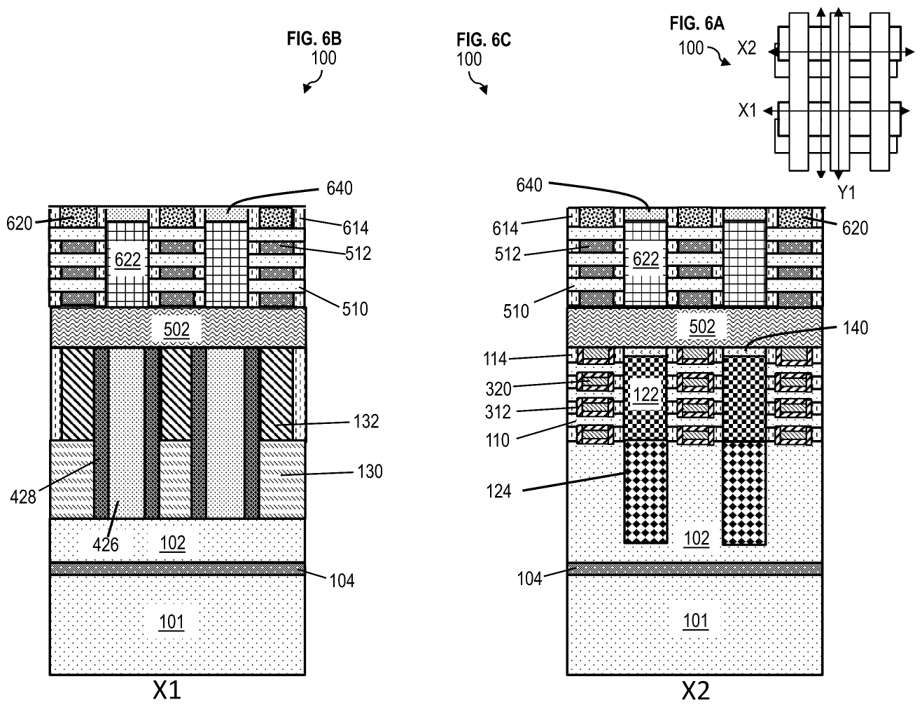

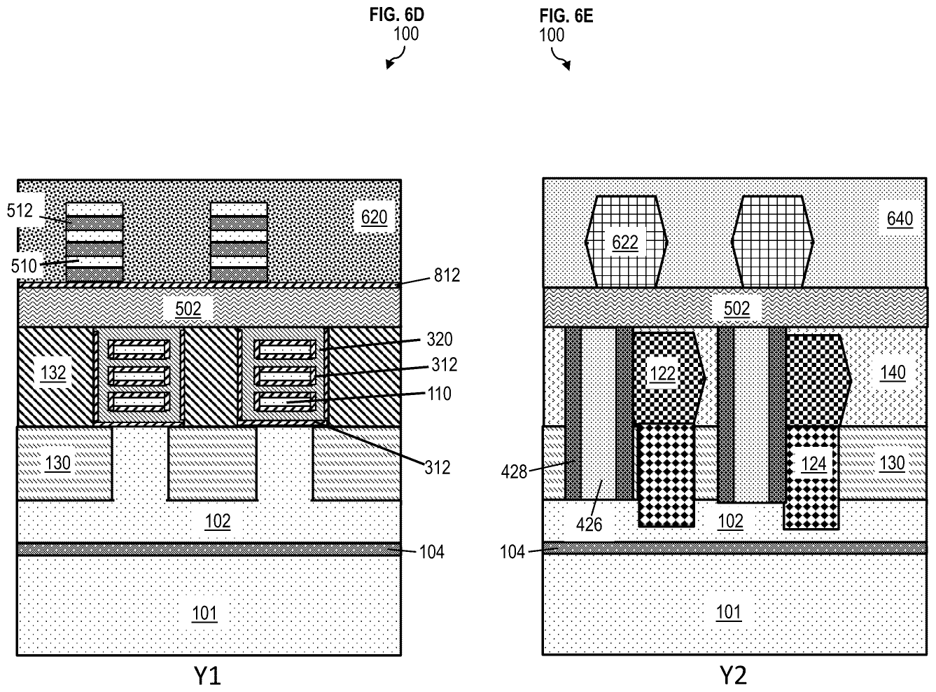

FIGS. 6A, 6B, 6C, 6D, and 6E depict the IC 100 after several fabrication processes. Fabrication processes may include active region patterning, dummy gate formation, space/inner spacer formation, source/drain epitaxial formation, and ILD formation.

Source and drain (source/drain) regions 622 are connected to the semiconductor layers 510. The source/drain regions 622 include epitaxial material that can be doped with n-type or p-type dopants according to whether an n-type or p-type transistor is formed. ILD material 640 is formed, which can include low-k-dielectric materials, ultra-low-k dielectric materials, etc.

After indenting the sacrificial layers 512, inner spacers 614 are formed between the semiconductor layers 510, and dummy gate 620 is formed. The dummy gate 620 can include silicon germanium or any suitable material for selective etching.

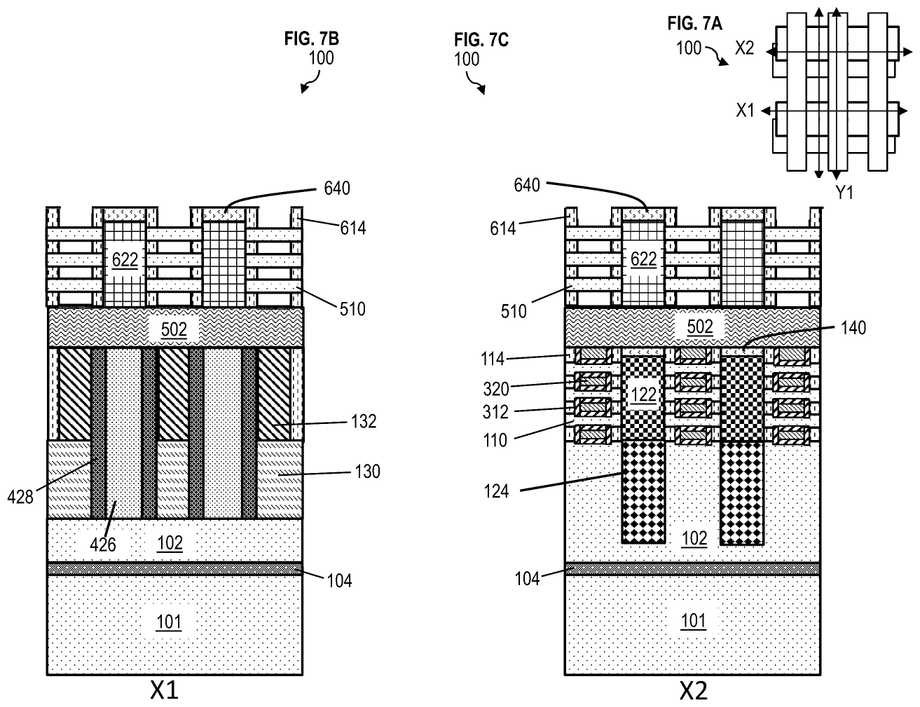

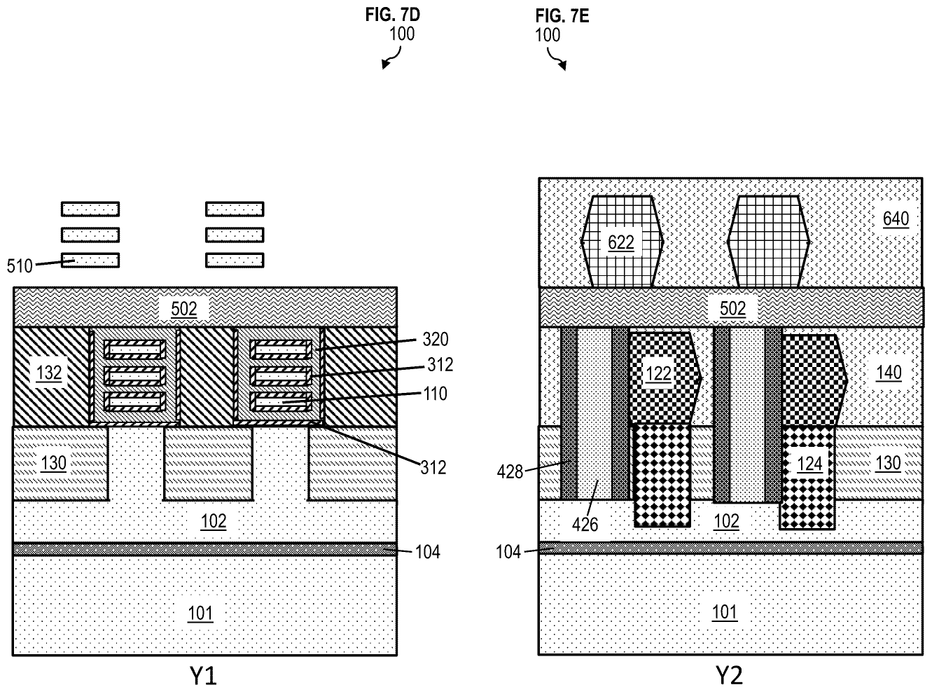

FIGS. 7A, 7B, 7C, 7D, and 7E depict the IC 100 after top dummy gate removal and sacrificial layer removal. Etching is performed to remove the dummy gate 620 and sacrificial layers 512, both of which can include silicon germanium for selective etching. This leaves openings around the semiconductor layers 510 in preparation for fill material.

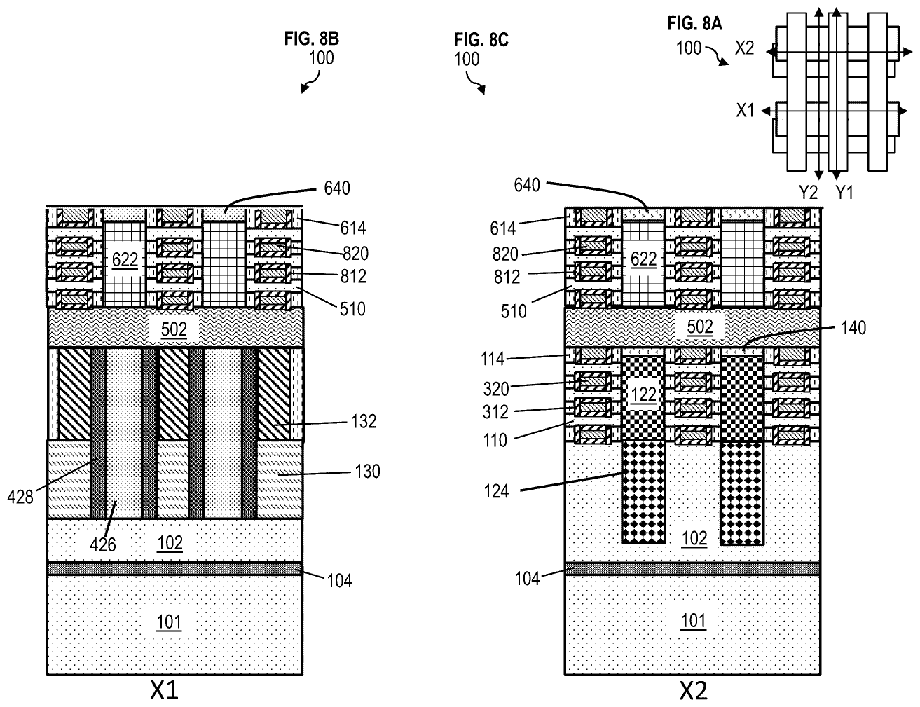

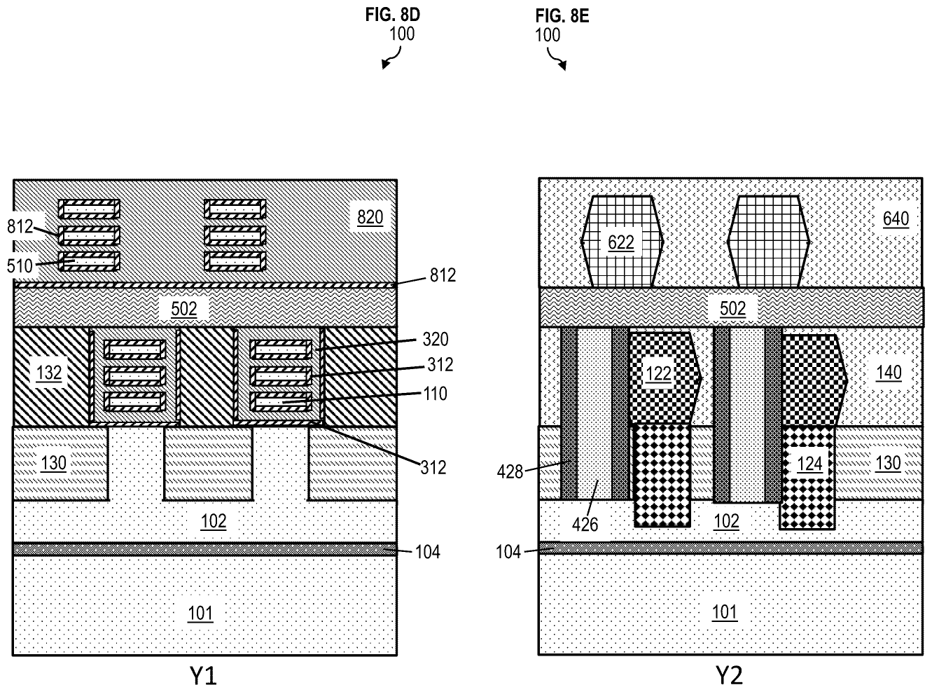

FIGS. 8A, 8B, 8C, 8D, and 8E depict the IC 100 after top high-k dielectric formation, fill material formation, and reliability anneal. High-k dielectric material 812 is formed around the semiconductor layers 510. As noted herein, there are many different materials that can be utilized for the high-k dielectric material 812, and examples of the high-k dielectric material 812 can include lanthanum oxide (LaOₓ) and aluminum oxide (AlOₓ). A fill material 820 is formed on the high-k dielectric material 812. The fill material 820 may be a stack of materials like the fill material 320. In one or more embodiments, the fill material 820 can include titanium nitride (TiN) material with amorphous silicon (a-Si) formed/stacked on top of the TiN material. The amorphous silicon may be formed as a cap. Further, it is noted that after the high-k dielectric deposition there could possibly be defects, and a high temperature anneal can be performed to repair those defects. However, the fill material 820 of the stacked TiN/a-Si serves as a sacrificial oxygen blocking layer during high-k reliability anneal, such that the fill material 820 prevents oxygen from diffusing through the high-k dielectric thereby preventing growth of SiO₂.

Annealing can be performed. A technical benefit is that the drive-in anneal for the high-k dielectric material 312 and the high-k dielectric material 812 can be performed (only) once, together for both the upper and lower transistors. CMP can be performed to polish away any excess material.

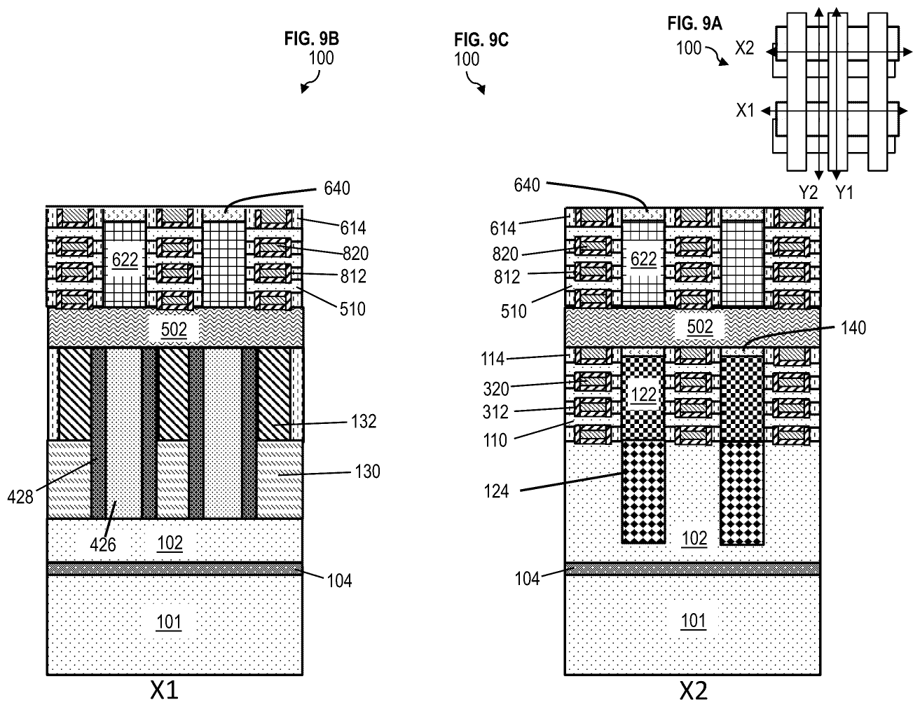

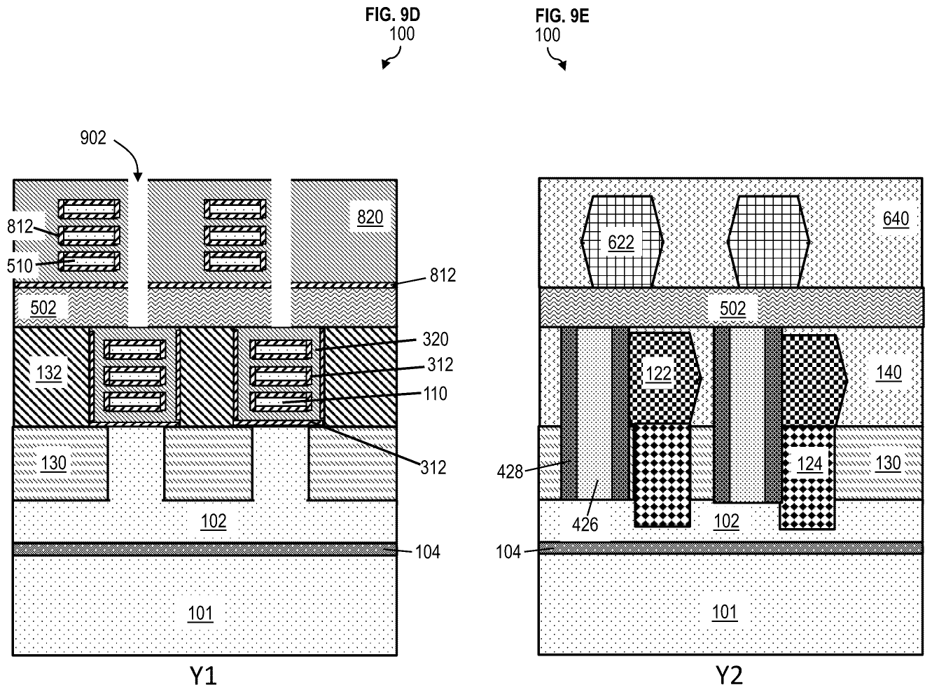

FIGS. 9A, 9B, 9C, 9D, and 9E depict the IC 100 after gate connection patterning. Gate connection patterning is performed to form vias 902 from the upper transistor to the lower transistor.

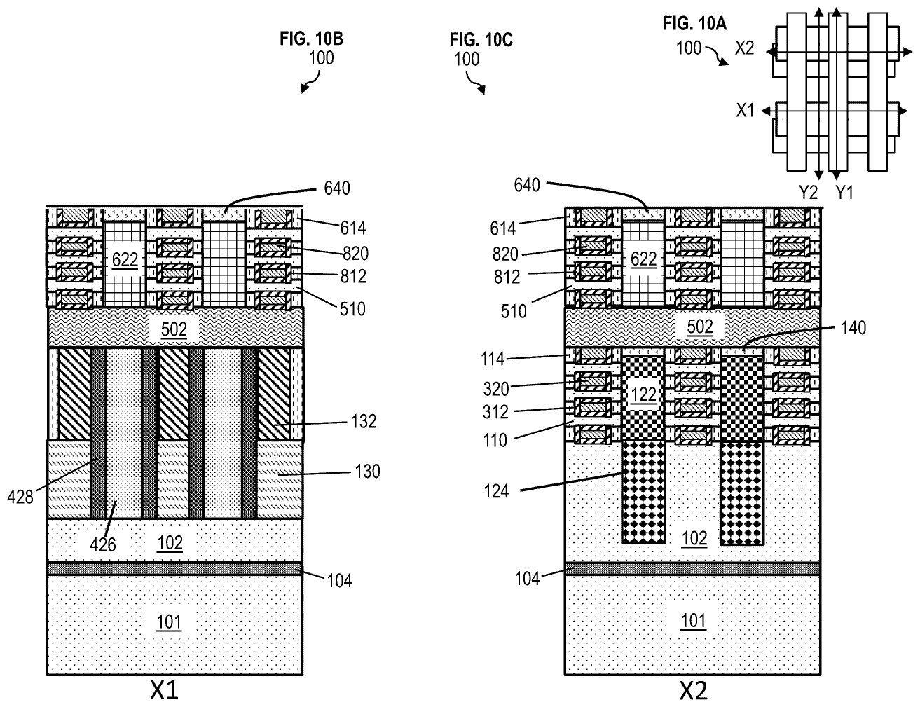

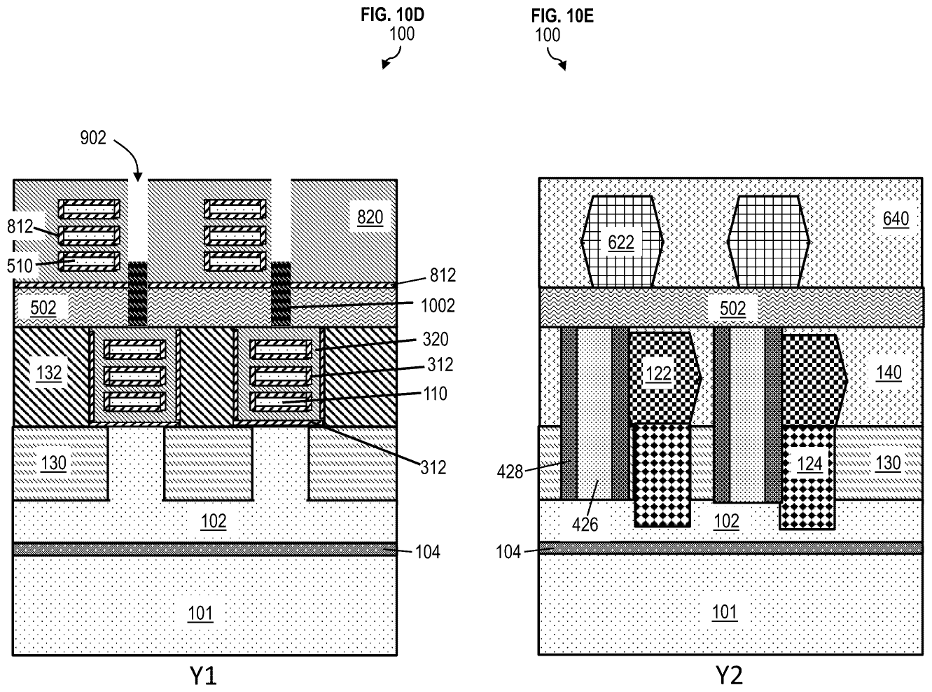

FIGS. 10A, 10B, 10C, 10D, and 10E depict the IC 100 after organic planarization layer (OPL) fill and recess to protect bottom fill material. Materials for OPL 1002 are deposited and recessed to remain in the vias 902. The OPL 1002 covers the (bottom) fill material 320, while the (top) fill material 820 is exposed for etching.

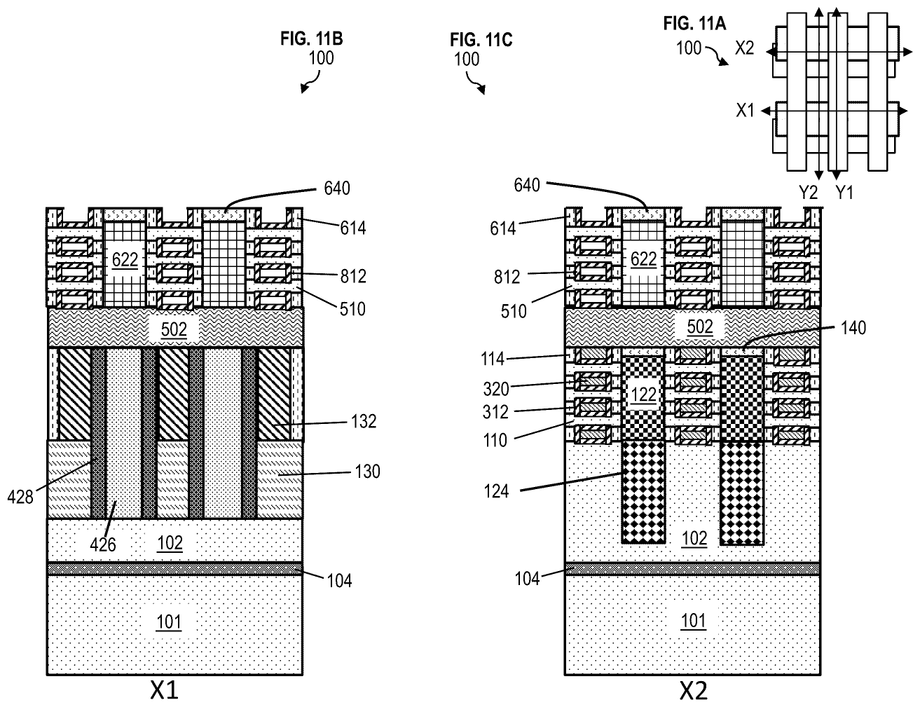

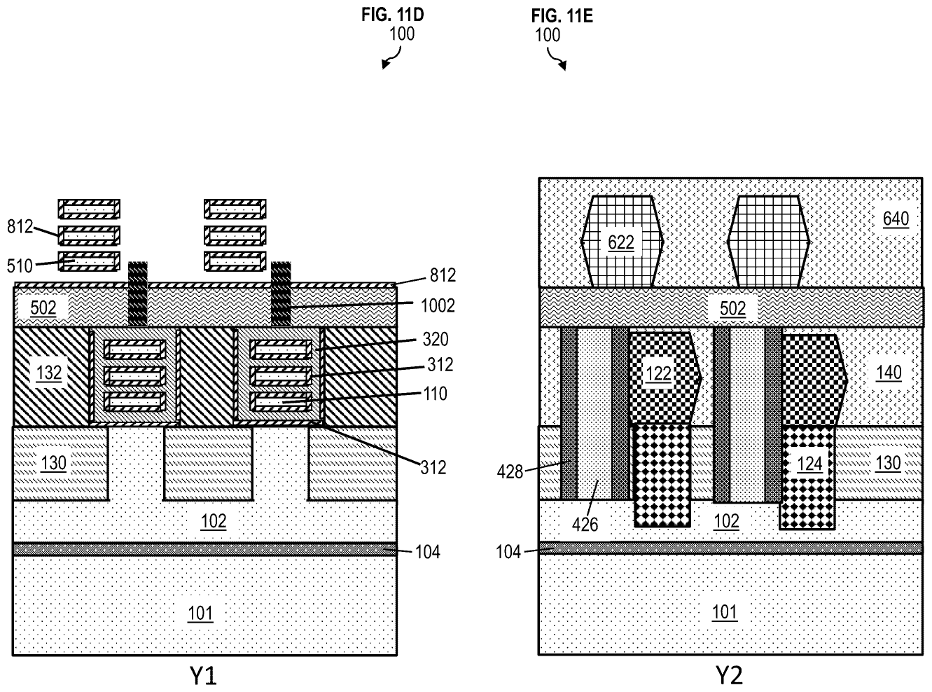

FIGS. 11A, 11B, 11C, 11D, and 11E depict the IC 100 after removing the top fill material. Selective etching can be performed to remove the (exposed) fill material 820. In one or more embodiments, the stack can be a TiN/a-Si stack. In one or more embodiments, an ammonia wet etch can be utilized to remove the amorphous silicon material, and a Standard Clean 1 (SC1) clean can be utilized to remove the titanium nitride material. The OPL 1002 protects the (bottom) fill material 320 during the etching process.

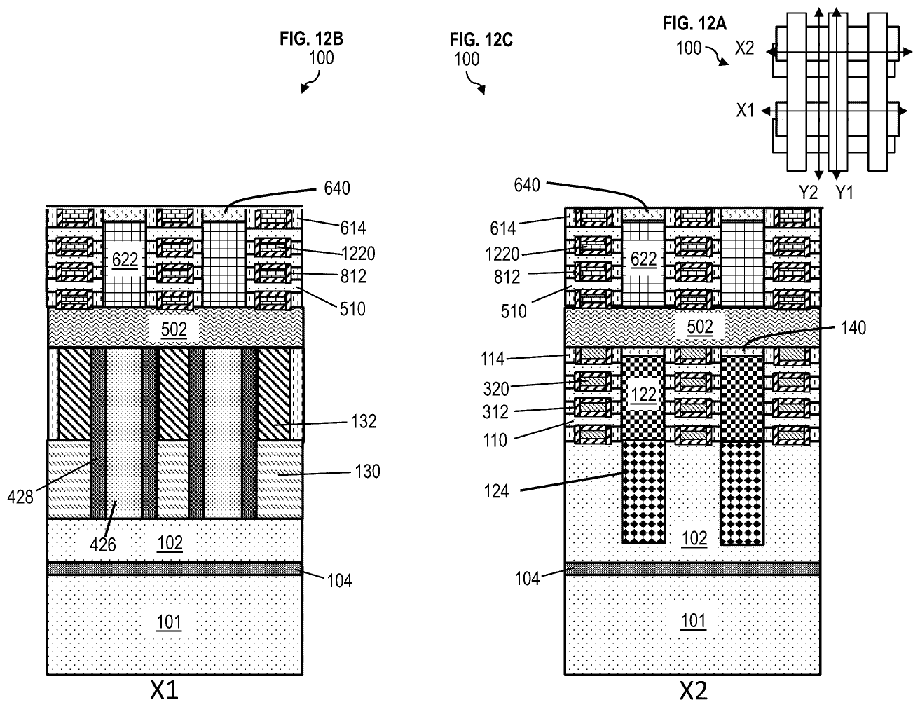

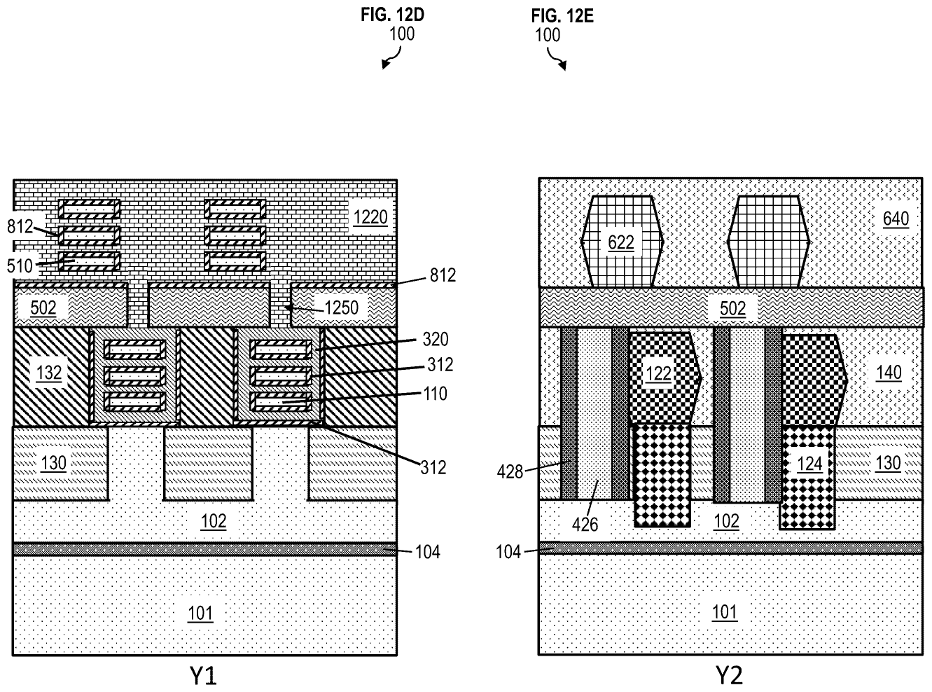

FIGS. 12A, 12B, 12C, 12D, and 12E depict the IC 100 after an OPL ash and top work function metal formation. The OPL 1002 can be removed, and a work function material 1220 is formed around the high-k dielectric material 812. The work function material 1220 also forms gate connectors 1250 that connect the gates of the upper transistor and lower transistor. The work function materials/metals utilized can be for p-type transistors or n-type transistors. Gate metal, such as tungsten or other materials, may be added to fill any additional space. The high-k dielectric material 812 and the work function material 1220 together form a top gate for the upper transistor.

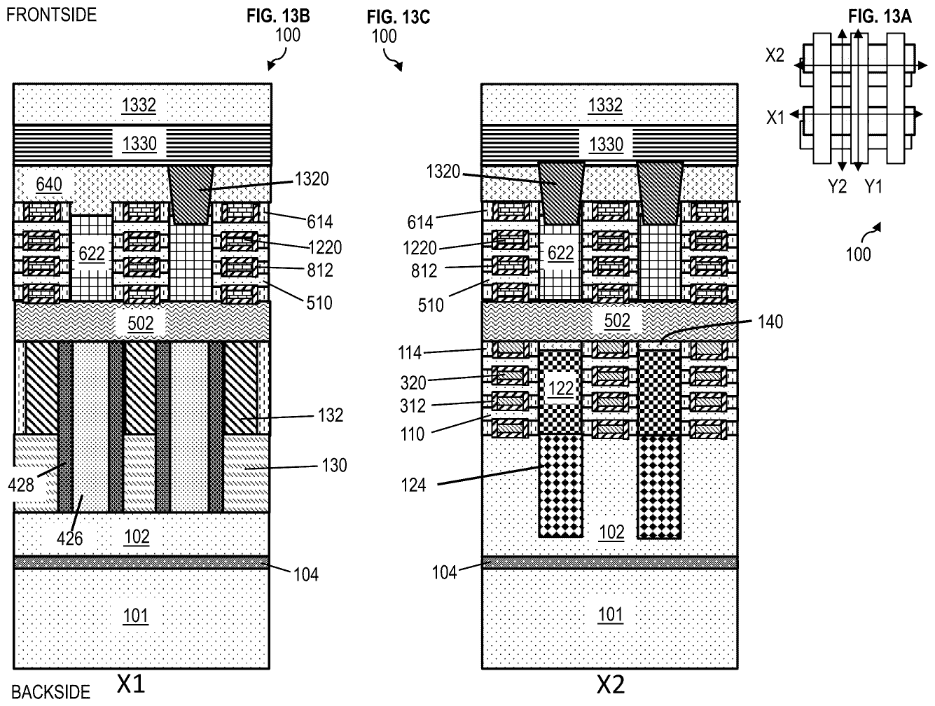

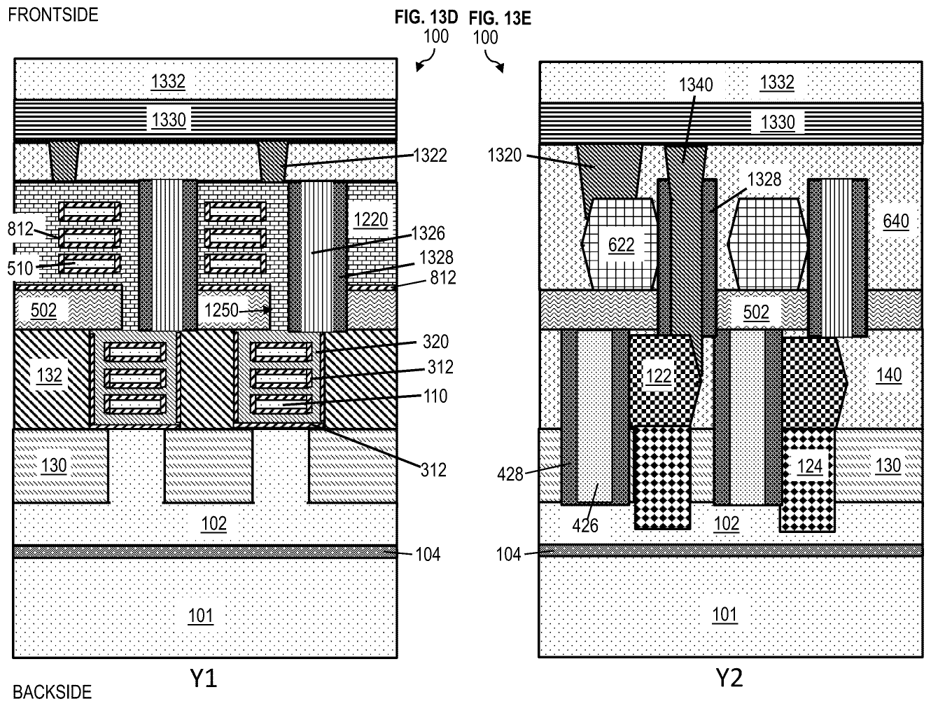

FIGS. 13A, 13B, 13C, 13D, and 13E depict the IC 100 after gate cuts and middle-of-line (MOL) and back-of-line (BEOL) formation. Lithography is performed to form gate cuts into the top gate for the upper transistors. Gate cuts are formed in the work function material 1220, the (top) ILD material 640, a portion of the (top) source/drain regions 622, the bonding layer 502, and a portion of the (bottom) ILD material 140. The gate cuts are structures that include filled trenches 1326 with liners 1328 on the sides. Example materials of the filled trenches 1326 may include oxide materials. The liner 1328 can include nitride materials such as SiN, SiBCN, SiOCN, etc. Materials of the liner 1328 and the filled trenches 1326 are selected to have etch selectivity with respect to each other.

Additional material of the ILD material 640 is deposited, and frontside S/D contacts 1320, frontside gate contacts 1322, and frontside S/D contact 1340 are formed. In one or more embodiments, the material of one or more of the filled trenches 1326 can be removed and filled with conductive material to form the frontside S/D contact 1340 that extends from the frontside down to the (bottom) source/drain regions 122 of the lower transistors. The contacts may be referred to as metal contacts. Example conductive materials of the contacts can include tungsten, titanium, titanium nitride, aluminum, nickel, chromium, copper, gold, etc., along with various combinations and liners.

BEOL processing can be performed to form a frontside interconnect layer 1330, and a carrier wafer 1332 is bonded on the frontside interconnect layer 1330 in preparation for wafer flip.

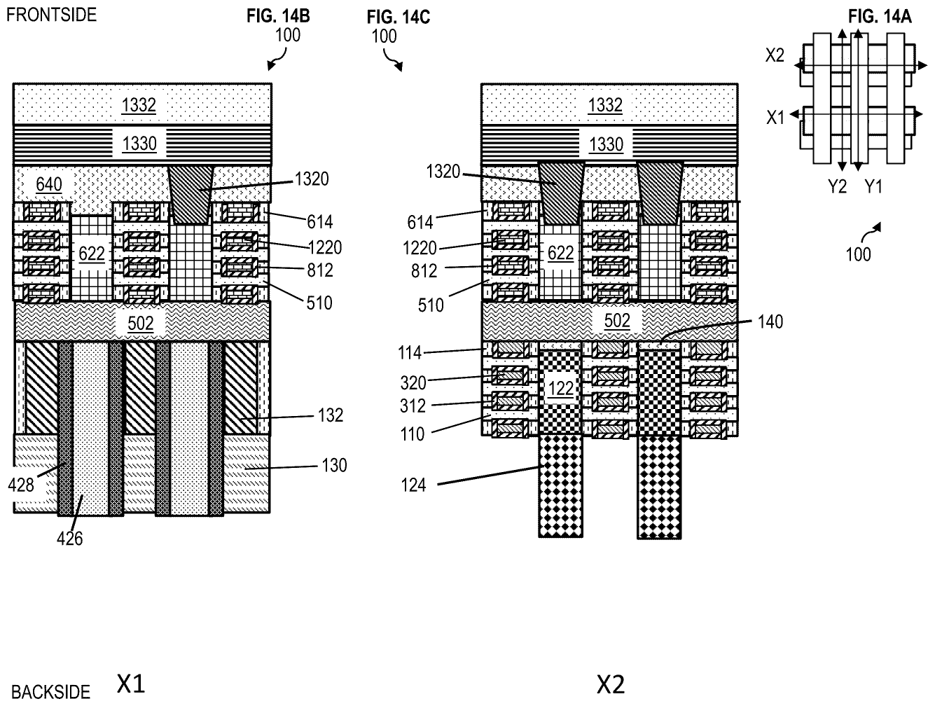

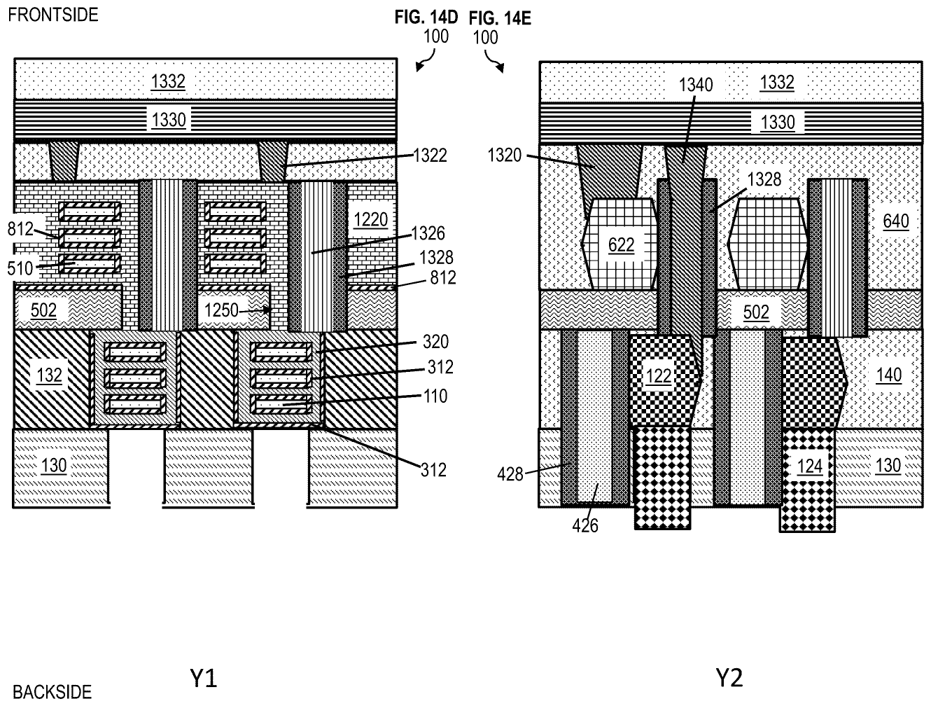

FIGS. 14A, 14B, 14C, 14D, and 14E depict the IC 100 after wafer flip and lower substrate, etch stop layer, and upper substrate removal. The wafer is flipped, and processing continues on the backside of the semiconductor structure. For consistency and to assist the reader, the wafer is not illustrated as being flipped in the figures, although it is understood that the wafer is flipped with fabrication processing performed on the backside.

The lower substrate 101 is removed to expose the etch stop layer 104. Etching and/or chemical mechanical polishing/planarization (CMP) may be utilized to remove the lower substrate 101. Etching can be performed to remove the etch stop layer 104 and the substrate 102, exposing portions of the high-k dielectric material 312.

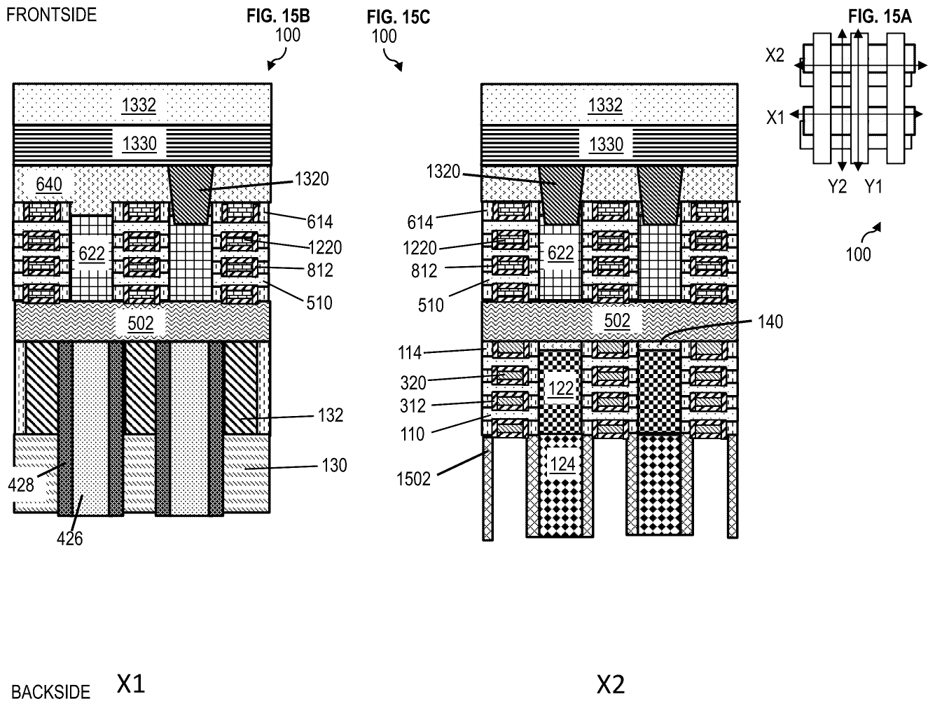

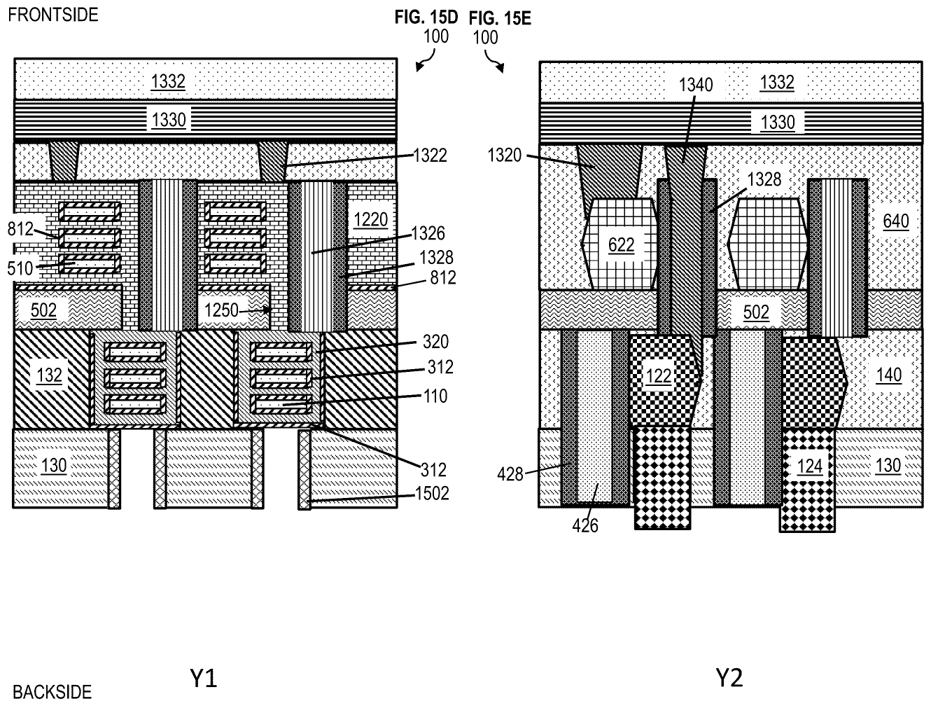

FIGS. 15A, 15B, 15C, 15D, and 15E depict the IC 100 after forming a protective spacer. A protective spacer 1502 is formed and recessed. The protective spacer is a nitride-based material. Example materials of the protective spacer 1502 may include SiN, SiBCN, SiOCN, SiOC, SiCN, SiO₂, etc.

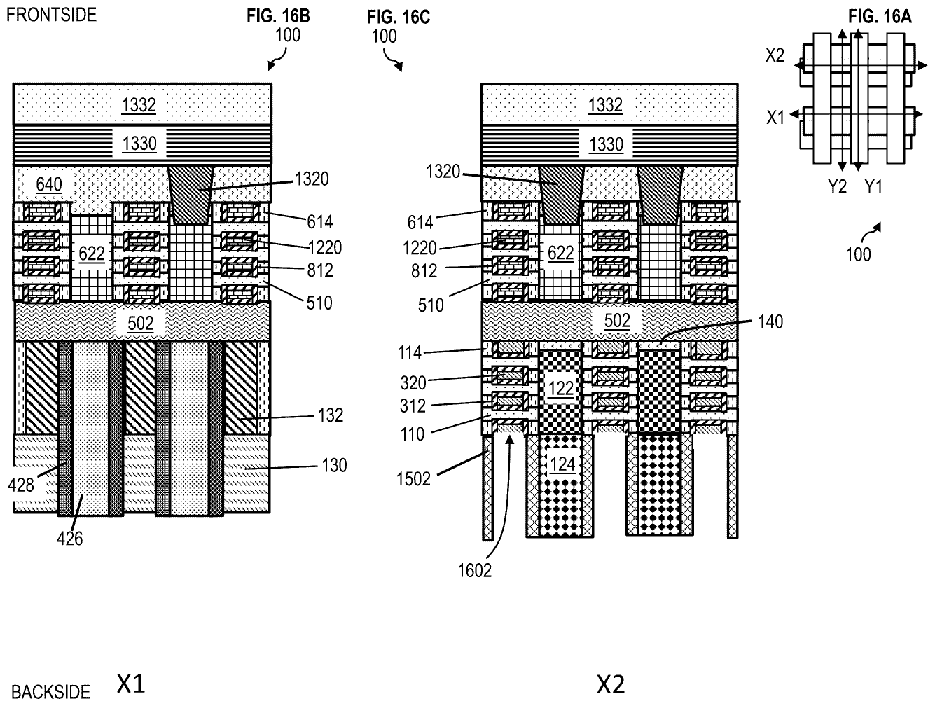

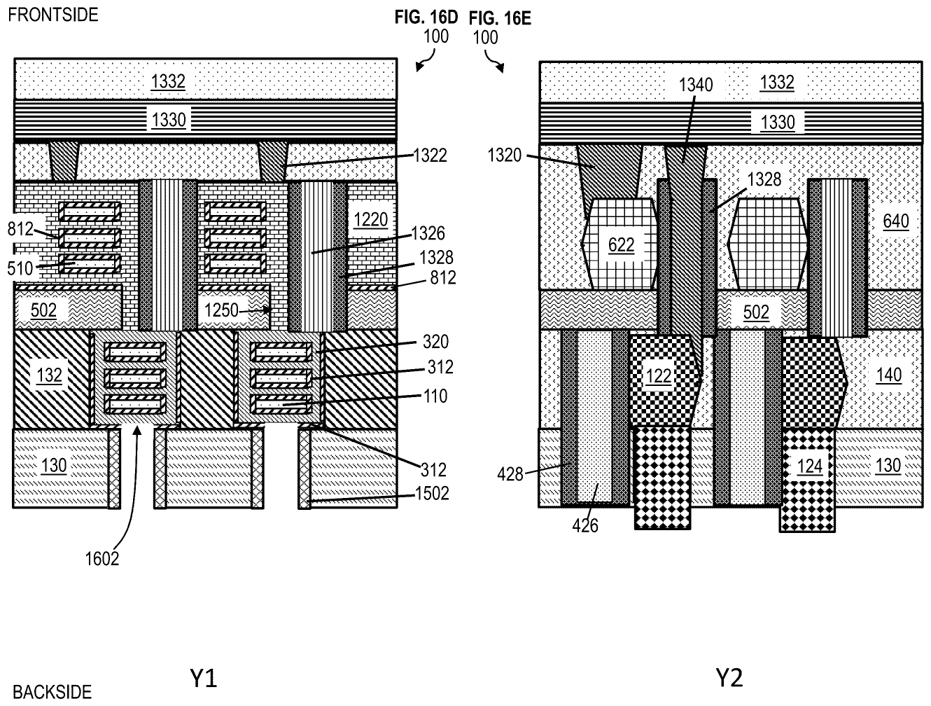

FIGS. 16A, 16B, 16C, 16D, and 16E depict the IC 100 after removal of the exposed high-k dielectric material of the lower transistor. Exposed portions of the high-k dielectric material 312 are etched such that the (bottom) fill material 320 is exposed for subsequent removal, thereby resulting in openings 1602 in the high-k dielectric material 312 of the lower transistor.

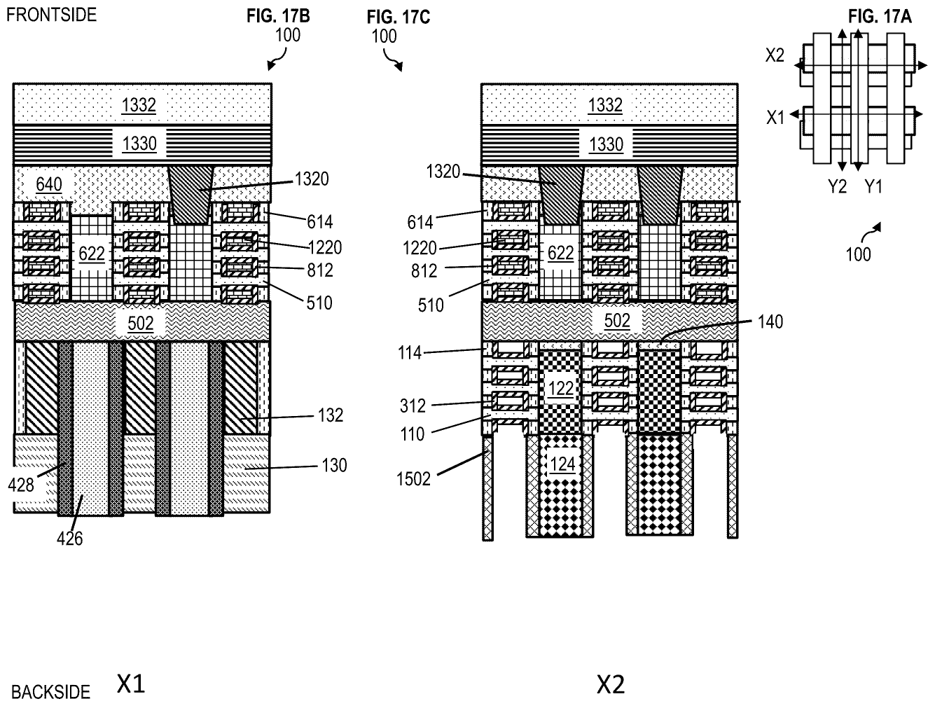

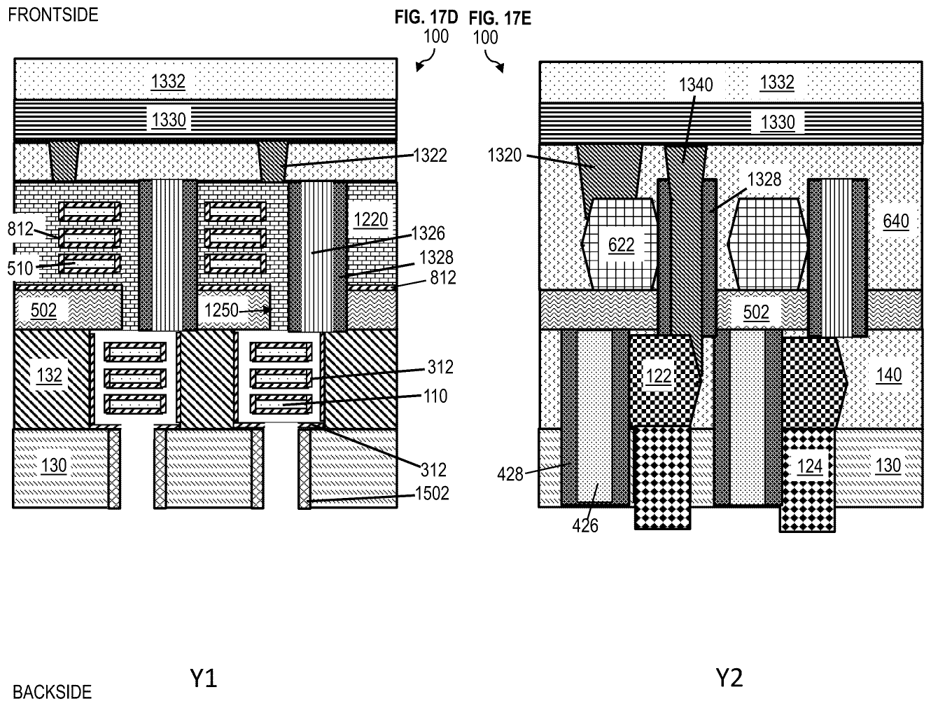

FIGS. 17A, 17B, 17C, 17D, and 17E depict the IC 100 after removal of the bottom fill material. Using the openings 1602, etching is performed to selectively remove the fill material 320, such that the lower transistor is prepared for work function material deposition. It is noted that the (bottom) high-k dielectric material 312 remains on the lower transistor except for the portion previously removed to form openings 1602.

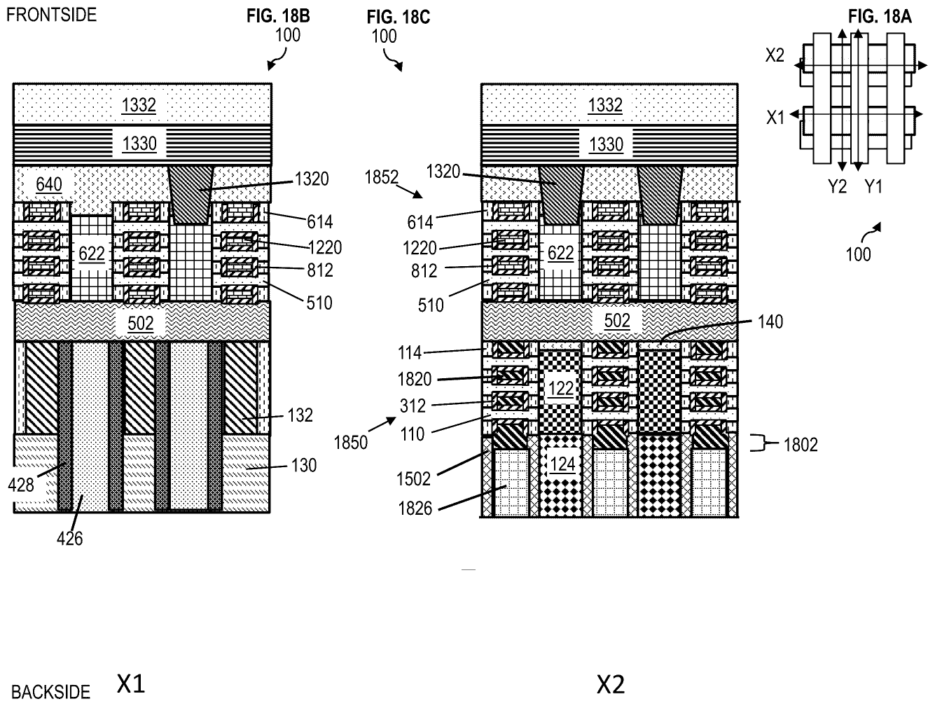

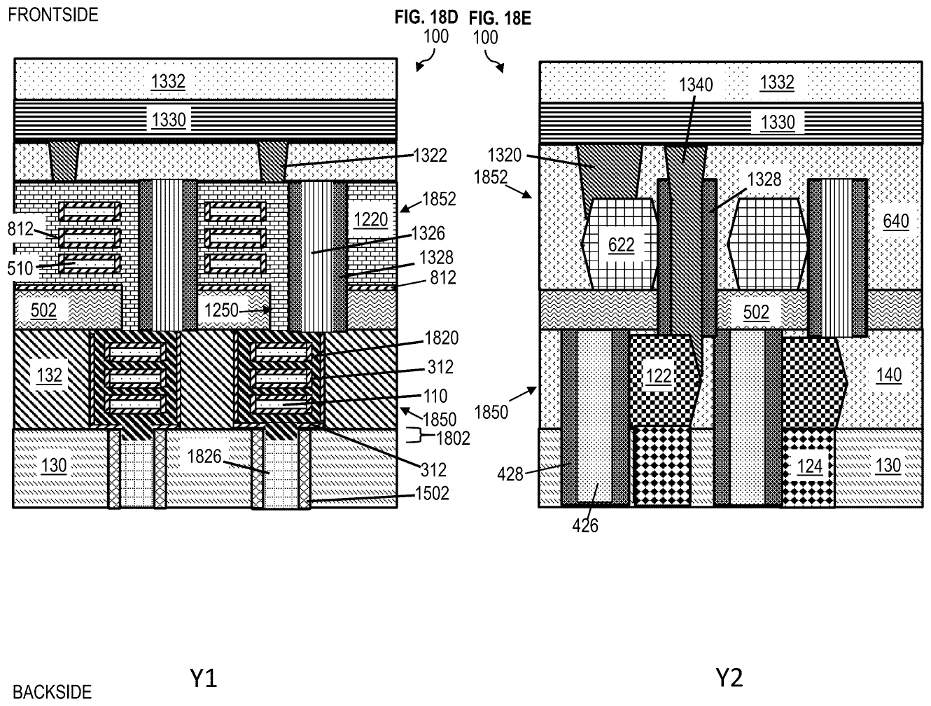

FIGS. 18A, 18B, 18C, 18D, and 18E depict the IC 100 after backside replacement gate formation and forming backside gate caps. A work function material 1820 is formed around the high-k dielectric material 312, and backside gate caps 1826 are formed on the work function material 1820. Example materials of the backside gate caps 1826 may include nitride-based materials. The work function materials/metals are utilized to p-type transistors or n-type transistors. Gate metal, such as tungsten or other materials, may be added to fill any additional space. The high-k dielectric material 312 and the work function material 1820 together form a bottom gate for a lower transistor 1850.

As can be seen, an upper transistor 1852 is stacked over the lower transistor 1850. An extension 1802 of the work function material 1820 extends below the bottom-most portion of the high-k dielectric material 312 through the openings 1602 (as depicted in FIGS. 16A, 16B, 16C, 16D, and 16E) in the high-k dielectric material 312.

In one or more embodiments, the lower transistor 1850 and the upper transistors 1852 can each have different threshold voltages. The lower transistor 1850 can have a super-low threshold voltage or a low threshold voltage, while the upper transistor 1852 can have a medium threshold voltage or a high threshold voltage. The upper transistor 1852 and the lower transistor 1850 can have complimentary polarities. For example, the upper transistor 1852 can be a p-type transistor (PFET) while the lower transistor 1850 can be an n-type transistor (NFET), or vice versa.

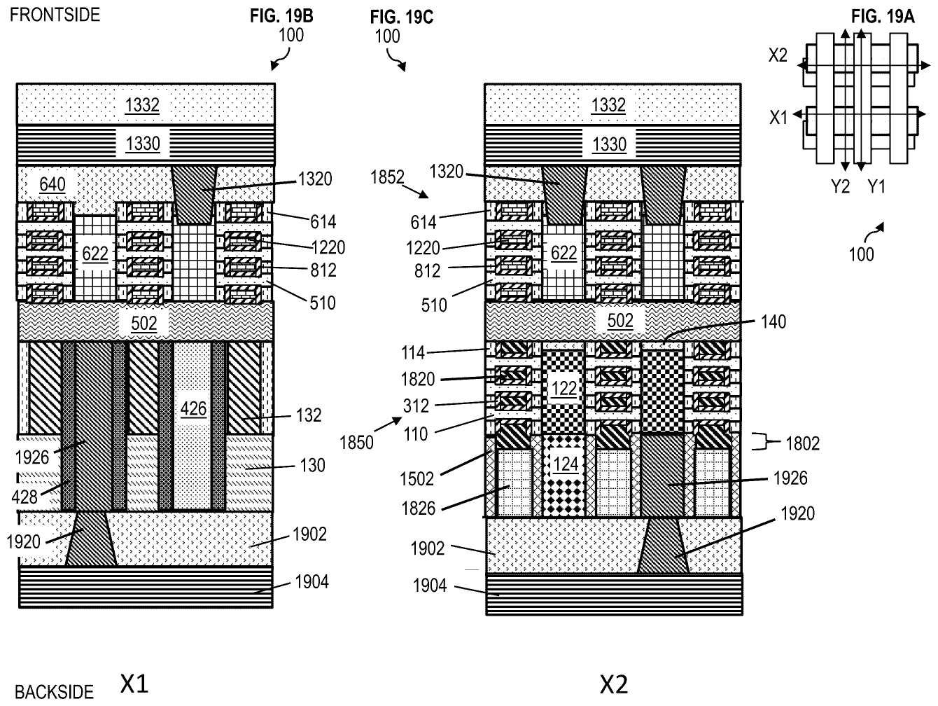

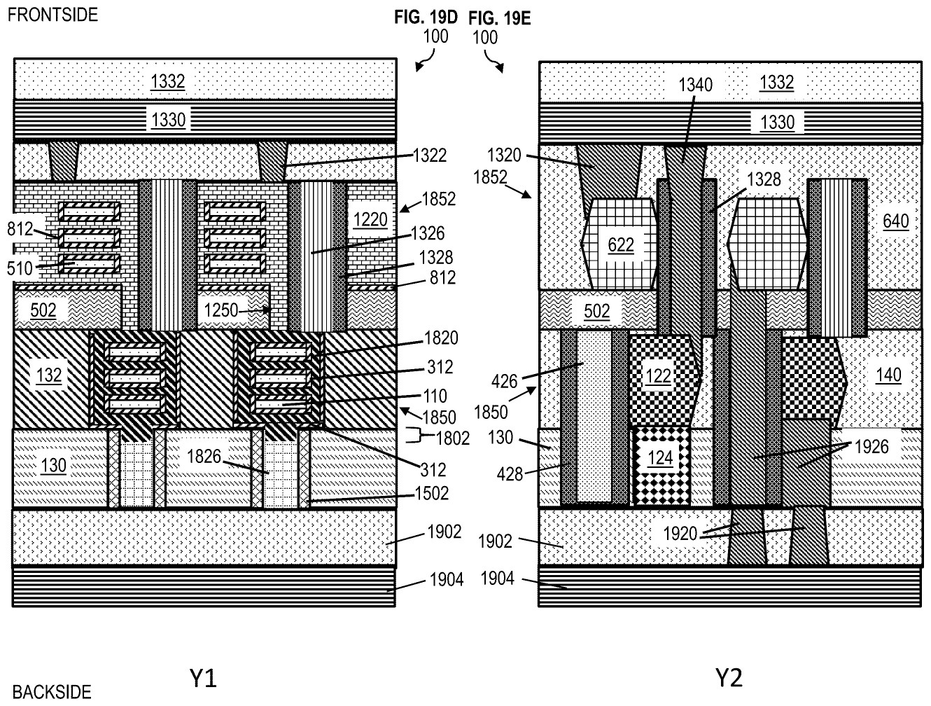

FIGS. 19A, 19B, 19C, 19D, and 19E depict the IC 100 after backside placeholder removal, backside contact formation, and backside interconnect formation. Lithography can be performed to etch some of the backside contact placeholders 124 and 426 and then fill their cavities with conductive material in order to form backside S/D contacts 1926. In some cases, further etching may be performed through the bonding layer 502 to expose the (top) source/drain regions 622. ILD material 1902 is deposited, and vias 1920 can be formed. The contacts may be referred to as metal contacts. Example conductive materials of the contacts and vias can include tungsten, titanium, titanium nitride, aluminum, nickel, chromium, copper, gold, etc., along with various combinations and liners. A backside interconnect layer 1904 is formed on the vias 1920.

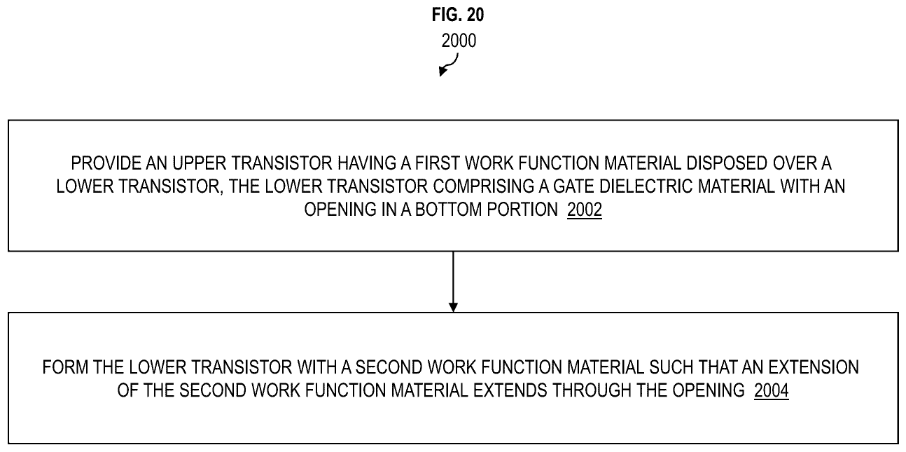

FIG. 20 is a flowchart of a method 2000 for forming an IC 100 with work function material/metal fill from the backside according to one or more embodiments. Reference can be made to any figures discussed herein. At block 2002, the method 2000 includes providing an upper transistor 1852 having a first work function material (e.g., work function material 1220) disposed over a lower transistor 1850, the lower transistor 1850 including a gate dielectric material (e.g., high-k dielectric material 312) with an opening 1602 in a bottom portion. At block 2004, the method 2000 includes forming the lower transistor 1850 with a second work function material (e.g., work function material 1820) such that an extension 1802 of the second work function material extends through the opening 1602.

The extension 1802 extends below the gate dielectric material (e.g., high-k dielectric material 312). The lower transistor 1850 includes source/drain regions 122, and a placeholder (e.g., backside contact placeholders 124) is coupled to one of the source/drain regions 122. A placeholder (e.g., backside contact placeholders 124) is under a source/drain region 122 of the lower transistor 1850, a spacer (e.g., protective spacer 1502) separating the placeholder (e.g., backside contact placeholders 124) from the extension 1802.

A backside contact (e.g., backside S/D contacts 1926) is coupled to a source/drain region 122 of the lower transistor 1850, a spacer (e.g., protective spacer 1502) separating the backside contact (e.g., backside S/D contacts 1926) from the extension 1802. A gate connector 1250 connects the first work function material (e.g., work function material 1220) to the second work function material (e.g., work function material 1820). The first work function is different from the second work function material.

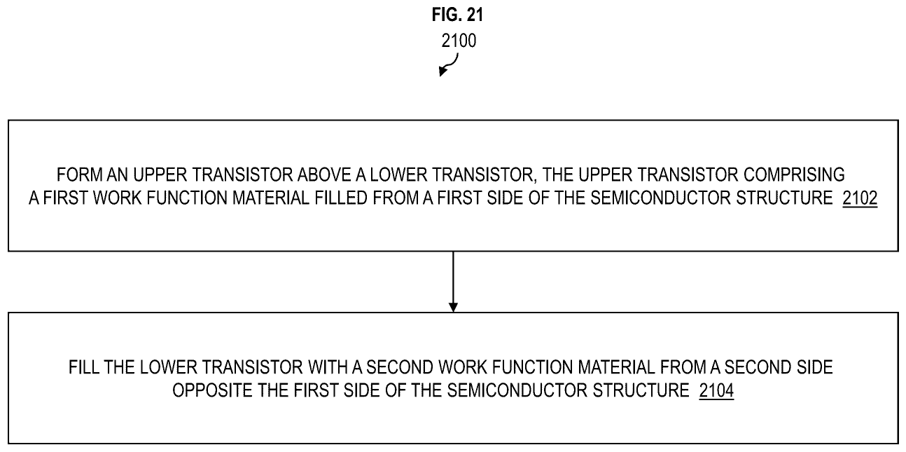

FIG. 21 is a flowchart of a method 2100 for forming an IC 100 with work function material/metal fill from the backside according to one or more embodiments. Reference can be made to any figures discussed herein. At block 2102, the method 2100 includes forming an upper transistor 1852 above a lower transistor 1850, the upper transistor 1852 includes a first work function material (e.g., work function material 1220) filled from a first side (e.g., frontside) of the semiconductor structure. At block 2104, the method 2100 includes filling the lower transistor 1850 with a second work function material (e.g., work function material 1820) from a second side (e.g., backside) opposite the first side of the semiconductor structure.

According to one or more embodiments, filling the lower transistor 1850 with the second work function material from the second side includes: forming an opening 1602 in a bottom portion of a gate dielectric material (e.g., high-k dielectric material 312) of the lower transistor 1850 so as to expose a sacrificial material (e.g., fill material 320) of the lower transistor; removing the sacrificial material (e.g., fill material 320) to expose the gate dielectric material (e.g., high-k dielectric material 312) surrounding channel regions (e.g., semiconductor layers 110; and depositing the second work function material from the second side. The lower transistor 1850 includes a gate dielectric material (e.g., high-k dielectric material 312) such that a bottom portion of the gate dielectric material has an opening 1602, and an extension 1802 of the second work function material (e.g., work function material 1820) extends through the opening 1602.

As discussed herein, gate material is formed around the semiconductor layers. The gate material includes high-k material and work function material generally referred to as a high-k metal gate (HKMG). Techniques for forming HKMG in gate openings are well-known in the art and, thus, the details have been omitted in order to allow the reader to focus on the salient aspects of the disclosed methods. However, it should be understood that such HKMG will generally include formation of one or more gate dielectric layers (e.g., an inter-layer (IL) oxide and a high-k gate dielectric layer), which are deposited so as to line the gate openings, and formation of one or more metal layers, which are deposited onto the gate dielectric layer(s) so as to fill the gate openings. The materials and thicknesses of the dielectric and metal layers used for the HKMG can be preselected to achieve desired work functions given the conductivity type of the FET. To avoid clutter in the drawings and to allow the reader to focus on the salient aspects of the disclosed methods, the different layers within the HKMG stack are not illustrated. For explanation purposes, a high-k gate dielectric layer can be, for example, a dielectric material with a dielectric constant that is greater than the dielectric constant of silicon dioxide (i.e., greater than 3.9). Exemplary high-k dielectric materials include, but are not limited to, hafnium (Hf)-based dielectrics (e.g., hafnium oxide, hafnium silicon oxide, hafnium silicon oxynitride, hafnium aluminum oxide, etc.) or other suitable high-k dielectrics (e.g., aluminum oxide, tantalum oxide, zirconium oxide, etc.). Optionally, the metal layer(s) can include a work function metal that is immediately adjacent to the gate dielectric layer and that is preselected in order to achieve an optimal gate conductor work function given the conductivity type of the nanosheet-FET. For example, the optimal gate conductor work function for the PFETs can be, for example, between about 4.9 eV and about 5.2 eV. Exemplary metals (and metal alloys) having a work function within or close to this range include, but are not limited to, ruthenium, palladium, platinum, cobalt, and nickel, as well as metal oxides (aluminum carbon oxide, aluminum titanium carbon oxide, etc.) and metal nitrides (e.g., titanium nitride, titanium silicon nitride, tantalum silicon nitride, titanium aluminum nitride, tantalum aluminum nitride, etc.). The optimal gate conductor work function for NFETs can be, for example, between 3.9 eV and about 4.2 eV. Exemplary metals (and metal alloys) having a work function within or close to this range include, but are not limited to, hafnium, zirconium, titanium, tantalum, aluminum, and alloys thereof, such as, hafnium carbide, zirconium carbide, titanium carbide, tantalum carbide, and aluminum carbide. The metal layer(s) can further include a fill metal or fill metal alloy, such as tungsten, a tungsten alloy (e.g., tungsten silicide or titanium tungsten), cobalt, aluminum, or any other suitable fill metal or fill metal.

Although not shown in detail, contact formation and ILD formation are performed. As such, ILD material can be deposited, source/drain contact openings are patterned by conventional lithography, and then metal is deposited to fill the cavities thereby forming metal contacts. A portion of the metal contacts may include silicide, resulting from the interface of the metal material and semiconductor material. The metal contacts are source/drain contacts that are respectively connected to epitaxial source/drain regions.

The ILD material can be SiO₂, SiN, a low-k dielectric material or an ultra-low-k dielectric material. Low-k dielectric materials may generally include dielectric materials having a k value of about 3.9 or less. The ultra-low-k dielectric material generally includes dielectric materials having a k value less than 2.5. Unless otherwise noted, all k values mentioned in the present application are measured relative to a vacuum. Exemplary ultra-low-k dielectric materials generally include porous materials such as porous organic silicate glasses, porous polyamide nanofoams, silica xerogels, porous hydrogen silsequioxane (HSQ), porous methylsilsesquioxane (MSQ), porous inorganic materials, porous CVD materials, porous organic materials, or combinations thereof. The ultra-low-k dielectric material can be produced using a templated process or a sol-gel process as is generally known in the art. In the templated process, the precursor typically contains a composite of thermally labile and stable materials. After film deposition, the thermally labile materials can be removed by thermal heating, leaving pores in the dielectric film. In the sol gel process, the porous low-k dielectric films can be formed by hydrolysis and polycondensation of an alkoxide(s) such as tetraetehoxysilane (TEOS).

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The phrase “selective to,” such as, for example, “a first element selective to a second element,” means that the first element can be etched and the second element can act as an etch stop.

As used herein, “p-type” refers to the addition of impurities to an intrinsic semiconductor that creates deficiencies of valence electrons. In a silicon-containing substrate, examples of p-type dopants, i.e., impurities, include but are not limited to: boron, aluminum, gallium and indium.

As used herein, “n-type” refers to the addition of impurities that contributes free electrons to an intrinsic semiconductor. In a silicon containing substrate examples of n-type dopants, i.e., impurities, include but are not limited to antimony, arsenic and phosphorous.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

As noted above, atomic layer etching processes can be used in the present invention for via residue removal, such as can be caused by via misalignment. The atomic layer etch process provide precise etching of metals using a plasma-based approach or an electrochemical approach. The atomic layer etching processes are generally defined by two well-defined, sequential, self-limiting reaction steps that can be independently controlled. The process generally includes passivation followed selective removal of the passivation layer and can be used to remove thin metal layers on the order of nanometers. An exemplary plasma-based approach generally includes a two-step process that generally includes exposing a metal such a copper to chlorine and hydrogen plasmas at low temperature (below 20° C.). This process generates a volatile etch product that minimizes surface contamination. In another example, cyclic exposure to an oxidant and hexafluoroacetylacetone (Hhfac) at an elevated temperature such as at 275° C. can be used to selectively etch a metal such as copper. An exemplary electrochemical approach also can include two steps. A first step includes surface-limited sulfidization of the metal such as copper to form a metal sulfide, e.g., Cu₂S, followed by selective wet etching of the metal sulfide, e.g., etching of Cu₂S in HCl. Atomic layer etching is relatively recent technology and optimization for a specific metal is well within the skill of those in the art. The reactions at the surface provide high selectivity and minimal or no attack of exposed dielectric surfaces.

Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The photoresist can be formed using conventional deposition techniques such chemical vapor deposition, plasma vapor deposition, sputtering, dip coating, spin-on coating, brushing, spraying and other like deposition techniques can be employed. Following formation of the photoresist, the photoresist is exposed to a desired pattern of radiation such as X-ray radiation, extreme ultraviolet (EUV) radiation, electron beam radiation or the like. Next, the exposed photoresist is developed utilizing a conventional resist development process.

After the development step, the etching step can be performed to transfer the pattern from the patterned photoresist into the interlayer dielectric. The etching step used in forming at least one opening can include a dry etching process (including, for example, reactive ion etching, ion beam etching, plasma etching or laser ablation), a wet chemical etching process or any combination thereof.

For the sake of brevity, conventional techniques related to making and using aspects of the invention may or may not be described in detail herein. In particular, various aspects of computing systems and specific computer programs to implement the various technical features described herein are well known. Accordingly, in the interest of brevity, many conventional implementation details are only mentioned briefly herein or are omitted entirely without providing the well-known system and/or process details.

In some embodiments, various functions or acts can take place at a given location and/or in connection with the operation of one or more apparatuses or systems. In some embodiments, a portion of a given function or act can be performed at a first device or location, and the remainder of the function or act can be performed at one or more additional devices or locations.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The present disclosure has been presented for the purposes of illustration and description but is not intended to be exhaustive or limited to the form disclosed. Many modifications and variations will be apparent to those of ordinary skill in the art without departing from the scope and spirit of the disclosure. The embodiments were chosen and described in order to best explain the principles of the disclosure and the practical application, and to enable others of ordinary skill in the art to understand the disclosure for various embodiments with various modifications as are suited to the particular use contemplated.

The diagrams depicted herein are illustrative. There can be many variations to the diagram or the steps (or operations) described therein without departing from the spirit of the disclosure. For instance, the actions can be performed in a differing order or actions can be added, deleted or modified. Also, the term “coupled” describes having a signal path between two elements and does not imply a direct connection between the elements with no intervening elements/connections therebetween. All of these variations are considered a part of the present disclosure.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e., one, two, three, four, etc. The terms “a plurality” are understood to include any integer number greater than or equal to two, i.e., two, three, four, five, etc. The term “connection” can include both an indirect “connection” and a direct “connection.”

The terms “about,” “substantially,” “approximately,” and variations thereof, are intended to include the degree of error associated with measurement of the particular quantity based upon the equipment available at the time of filing the application. For example, “about”can include a range of ±8% or 5%, or 2% of a given value.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A semiconductor structure comprising:
an upper transistor having a first work function material disposed over a lower transistor, the lower transistor comprising a gate dielectric material and a second work function material such that a bottom portion of the gate dielectric material comprises an opening;
wherein an extension of the second work function material extends through the opening.

2. The semiconductor structure of claim 1, wherein the extension extends below the gate dielectric material.

3. The semiconductor structure of claim 1, wherein:
the lower transistor comprises source/drain regions; and
a placeholder is coupled to one of the source/drain regions.

4. The semiconductor structure of claim 1, wherein a placeholder is under a source/drain region of the lower transistor, a spacer separating the placeholder from the extension.

5. The semiconductor structure of claim 1, wherein a backside contact is coupled to a source/drain region of the lower transistor, a spacer separating the backside contact from the extension.

6. The semiconductor structure of claim 1, wherein a gate connector connects the first work function material to the second work function material.

7. The semiconductor structure of claim 1, wherein the first work function material is different from the second work function material.

8. A method comprising:
providing an upper transistor having a first work function material disposed over a lower transistor, the lower transistor comprising a gate dielectric material with an opening in a bottom portion; and
forming the lower transistor with a second work function material such that an extension of the second work function material extends through the opening.

9. The method of claim 8, wherein the extension extends below the gate dielectric material.

10. The method of claim 8, wherein:
the lower transistor comprises source/drain regions; and
a placeholder is coupled to one of the source/drain regions.

11. The method of claim 8, wherein a placeholder is under a source/drain region of the lower transistor, a spacer separating the placeholder from the extension.

12. The method of claim 8, wherein a backside contact is coupled to a source/drain region of the lower transistor, a spacer separating the backside contact from the extension.

13. The method of claim 8, wherein a gate connector connects the first work function material to the second work function material.

14. The method of claim 8, wherein the first work function material is different from the second work function material.

15. A method of forming a semiconductor structure, the method comprising:
forming an upper transistor above a lower transistor, the upper transistor comprising a first work function material filled from a first side of the semiconductor structure; and
filling the lower transistor with a second work function material from a second side opposite the first side of the semiconductor structure.

16. The method of claim 15, wherein the filling the lower transistor with the second work function material from the second side comprises:
forming an opening in a bottom portion of a gate dielectric material of the lower transistor so as to expose a sacrificial material of the lower transistor;
removing the sacrificial material to expose the gate dielectric material surrounding channel regions; and
depositing the second work function material from the second side.

17. The method of claim 15, wherein:
the lower transistor comprises a gate dielectric material such that a bottom portion of the gate dielectric material comprises an opening; and
an extension of the second work function material extends through the opening.

18. The method of claim 15, wherein an extension of the second work function material extends through an opening of a bottom portion of a gate dielectric material of the lower transistor, the extension extending below the gate dielectric material.

19. The method of claim 15, wherein:
an extension of the second work function material extends through an opening of a bottom portion of a gate dielectric material of the lower transistor; and
a placeholder is under a source/drain region of the lower transistor, a spacer separating the placeholder from the extension.

20. The method of claim 15, wherein:
an extension of the second work function material extends through an opening of a bottom portion of a gate dielectric material of the lower transistor; and
a backside contact is coupled to a source/drain region of the lower transistor, a spacer separating the backside contact from the extension.
